(19) United States
(12) Patent Application Publication
(10) Pub. No.: US 2023/0046352 A1
(43) Pub. Date: Feb. 16, 2023

(54) METHOD OF PRODUCING SEMICONDUCTOR DEVICE INCLUDING MEMORY ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP); Masakazu KAKUMU, Tokyo (JP)

(21) Appl. No.: 17/883,885

(22) Filed: Aug. 9, 2022

(30) Foreign Application Priority Data
Aug. 10, 2021 (JP) PCT/JP2021/029514

(51) Int. Cl. H01L 27/108

(52) U.S. Cl. CPC H01L 27/10802; H01L 27/10897; H01L 27/10873

(57) ABSTRACT

Material layers including first and second poly-Si layer are formed on a P-layer substrate. Holes which are parallel to each other and each of which is continuous in a first direction are formed in the material layers. The first and second poly-Si layers are each divided by the holes in a second direction orthogonal to the first direction in plan view. Gate insulating layers and P-layer Si pillars are formed in the holes. The P-layer Si pillars are isolated from one another by the gate insulating layers. A dynamic flash memory is formed in which a first gate conductor layer is connected to a plate line, a second gate conductor layer is connected to a word line, the P-layer Si pillars serve as channels, and one of the N⁺ layers below and above the P-layer Si pillars is connected to a source line.

### RELATED APPLICATIONS

This application claims priority to PCT/JP2021/029514, filed on Aug. 10, 2021, the entire content of which is incorporated herein by reference.

### BACKGROUND OF THE INVENTION

### 1. Field of the Invention

The present invention relates to a method of producing a semiconductor device including a memory element.

### 2. Description of the Related Art

In recent years, a higher degree of integration and a higher performance of a semiconductor device including a memory element have been desired in the development of LSI (Large Scale Integration) technology.

In typical planar MOS transistors, a channel extends in a horizontal direction along an upper surface of a semiconductor substrate. By contrast, in surrounding gate transistors (SGTs), a channel extends in a direction perpendicular to an upper surface of a semiconductor substrate (see, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Thus, SGTs can achieve a higher density of semiconductor devices than planar MOS transistors. With the use of such SGTs as selection transistors, a higher degree of integration can be achieved in memory devices such as a dynamic random access memory (DRAM) to which a capacitor is connected (see, for example, H. Chung, H. Kim, H. Kim, K. Kim, S. Kim, K. Dong, J. Kim, Y. C. Oh, Y. Hwang, H. Hong, G. Lin, and C. Chung: “4F2 DRAM Cell with Vertical Pillar Transistor (VPT)”, 2011 Proceeding of the European Solid-State Device Research Conference, (2011)), a phase change memory (PCM) to which a resistance change element is connected (see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)), a resistive random access memory (RRAM) (see, for example, T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007)), and a magneto-resistive random access memory (MRAM) in which the direction of a magnetic spin is changed with a current to change the resistance (see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)). There is also a capacitorless DRAM memory cell constituted by a single MOS transistor (see M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)). The present application relates to a semiconductor device that includes a dynamic flash memory that can be constituted only by a MOS transistor without any resistance change element or any capacitor.

FIGS. 9A to 9D illustrate a write operation of the aforementioned capacitorless DRAM memory cell constituted by a single MOS transistor, FIGS. 10A and 10B illustrate an issue in the operation of the capacitorless DRAM memory cell, and FIGS. 11A to 11C illustrate a read operation of the capacitorless DRAM memory cell (see M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010); J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOT”, IEEE JSSC, vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, and A. Nitayama: “Floating Body RAM Technology and its Scalability to 32 nm Node and Beyond”, IEEE IEDM (2006); and E. Yoshida: “A Capacitorless 1T-DRAM Technology Using Gate-Induced Drain-Leakage (GIDL) Current for Low-Power and High-Speed Embedded Memory”, IEEE IEDM (2006)).

FIGS. 9A to 9D illustrate a write operation of the DRAM memory cell. FIG. 9A illustrates a “1” write state. The memory cell is constituted by a source N⁺ layer 103 (hereinafter, a semiconductor region that contains a donor impurity at a high concentration is referred to as an “N⁺ layer”) which is formed in a silicon-on-insulator (SOI) substrate 100 and to which a source line SL is connected, a drain N⁺ layer 104 which is formed in the SOI substrate 100 and to which a bit line BL is connected, a gate conductor layer 105 to which a word line WL is connected, and a floating body 102 of a MOS transistor 110a. In this manner, the DRAM memory cell is constituted by the single MOS transistor 110a without any capacitor. A SiO₂ layer 101 of the SOI substrate 100 is in contact with the floating body 102 immediately under the floating body 102. When “1” is written in this memory cell constituted by the single MOS transistor 110a, the MOS transistor 110a is operated in a saturated region. Specifically, a channel 107 for electrons extending from the source N⁺ layer 103 has a pinch-off point 108 and does not reach the drain N⁺ layer 104 to which the bit line BL is connected. When a high voltage is applied to both the bit line BL connected to the drain N⁺ layer 104 and the word line WL connected to the gate conductor layer 105 and the MOS transistor 110a is operated at a gate voltage that is about ½ of the drain voltage, the electric field intensity is maximized at the pinch-off point 108 near the drain N⁺ layer 104. As a result, the accelerated electrons flowing from the source N⁺ layer 103 toward the drain N⁺ layer 104 collide with the Si lattice, and electron-hole pairs are generated by kinetic energy lost at the time of collision (impact ionization). Most of the generated electrons (not illustrated) reach the drain N⁺ layer 104. Only a small number of very hot electrons jump over a gate oxide film 109 to reach the gate conductor layer 105. The floating body 102 is charged with holes 106 simultaneously generated. In this case, since the floating body 102 is made of P-type Si, the generated holes 106 contribute to an increment of the majority carrier. The floating body 102 is filled with the generated holes 106. When the voltage of the floating body 102 becomes higher than that of the source N⁺ layer 103 by Vb or more, the further generated holes 106 are discharged to the source N⁺ layer 103. Vb is a built-in voltage of a PN junction between the source N⁺ layer 103 and the floating body 102 of the P-layer Si pillar, and is equal to about 0.7 V. FIG. 9B illustrates the floating body 102 charged to be saturated with the generated holes 106.

Now, a “0” write operation of a memory cell 110 will be described with reference to FIG. 9C. The memory cell 110a in which “1” is written and a memory cell 110b in which “0” is written are present at random for the common selection word line WL. FIG. 9C illustrates rewriting from the “1” write state to a “0” write state. When “0” is written, the voltage of the bit line BL is set to a negative bias, so that the PN junction between the drain N⁺ layer 104 and the floating body 102 of the P-layer Si pillar is forward biased. As a result, the holes 106 generated in the floating body 102 in the previous cycle flow into the drain N⁺ layer 104 connected to the bit line BL. When the write operation ends, two memory cell states, i.e., the memory cell 110a filled with the generated holes 106 (FIG. 9B) and the memory cell 110b from which the generated holes 106 are discharged (FIG. 9C), are obtained. The potential of the floating body 102 of the memory cell 110a filled with the holes 106 is higher than the potential of the floating body 102 without any generated holes 106. Thus, a threshold voltage of the memory cell 110a is lower than a threshold voltage of the memory cell 110b. FIG. 9D illustrates this state.

Now, an issue in the operation of this memory cell constituted by a single MOS transistor will be described with reference to FIGS. 10A and 10B. As illustrated in FIG. 10A, a capacitance C_{FB} of the floating body 102 is equal to the sum of a capacitance C_{WL} between the gate to which the word line WL is connected and the floating body 102, a junction capacitance C_{SL} of the PN junction between the source N⁺ layer 103 to which the source line SL is connected and the floating body 102, and a junction capacitance C_{BL} of the PN junction between the drain N⁺ layer 104 to which the bit line BL is connected and the floating body 102, and is denoted by

C_{FB}=C_{WL}+C_{BL}+C_{SL} (1).

Thus, if a word line voltage V_{WL} changes at the time of writing, the voltage of the floating body 102 that serves as a storage node (contact point) of the memory cell is also affected by the change. FIG. 10B illustrates this state. If the word line voltage V_{WL} rises from 0 V to V_{ProgWL} at the time of writing, the voltage V_{FB} of the floating body 102 also rises from V_{FB1}, which is a voltage in the initial state before the word line voltage V_{WL} changes, to V_{FB2} due to capacitive coupling with the word line WL. An amount of the voltage change ΔV_{FB} is denoted by

ΔV_{FB}=V_{FB2}−V_{FB1}=C_{WL}/(C_{WL}+C_{BL}+C_{SL})×V_{ProgWL} (2).

Here, β is denoted by

β=C_{WL}/(C_{WL}+C_{BL}+C_{SL}) (3)

and is referred to as a coupling ratio. In such a memory cell, the contribution ratio of C_{WL} is large. For example, C_{WL}:C_{BL}:C_{SL}=8:1:1 holds. In this case, β=0.8 holds. For example, if the voltage of the word line WL changes from 5 V which is the voltage at the time of writing to 0 V after the end of writing, the floating body 102 is subjected to change noise of as large as 5 V×β=4 V due to the capacitive coupling between the word line WL and the floating body 102. Thus, there is an issue in that a sufficient margin of the potential difference between the “1” potential and the “0” potential of the floating body 102 is not provided at the time of writing.

FIGS. 11A to 11C illustrate a read operation. FIG. 11A illustrates the “1” write state. FIG. 11B illustrates the “0” write state. However, even if Vb is written in the floating body 102 in writing of “1”, when the voltage of the word line WL returns to 0 V upon the completion of the writing, the voltage of the floating body 102 actually lowers to a negative bias. When “0” is written, the voltage of the floating body 102 further lowers to a negative bias. Thus, the margin of the potential difference between “1” and “0” cannot be made sufficiently large at the time of writing. This small operation margin is a big issue for the DRAM memory cell.

There are memory elements in each of which one memory cell is formed using two MOS transistors in an SOT layer (see, for example, US2008/0137394A1 and US2003/0111681A1). In these elements, an N⁺ layer that serves as a source or a drain and isolates floating body channels of the two MOS transistors is formed in contact with an insulating layer. As a result of this N⁺ layer being in contact with the insulating layer, the floating body channels of the two MOS transistors are electrically isolated from each other. One of the MOS transistors is used for storing signal charges, and the other MOS transistor is used as a switch for signal reading. The signal charges are stored in only one of the MOS transistors. Thus, as described above, the voltage of the isolated floating body channel in which a group of holes serving as the signal charges is accumulated greatly changes in response to application of a pulse voltage to gate electrodes of the respective MOS transistors as indicated by Equation (2). Thus, there is an issue in that the margin of the potential difference between “1” and “0” cannot be made sufficiently large at the time of writing (see, for example, F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOT”, TEICE Trans. Electron., Vol. E90-c., No. 4, pp. 765-771 (2007), FIG. 8). Desirably, these memory cells are formed to have a higher density.

### SUMMARY OF THE INVENTION

In a capacitorless single-transistor DRAM (gain cell) that is a memory device using an SGT, the capacitive coupling between a word line and a SGT body in a floating state is large. Thus, the capacitorless single-transistor DRAM (gain cell) has an issue in that when the potential of the word line changes at the time of data reading or data writing, the change of the potential is directly transmitted as noise to the SGT body. This consequently causes an issue of erroneous reading and erroneous rewriting of stored data and makes it difficult to put the capacitorless single-transistor DRAM (gain cell) into practical use. Thus, the issues described above are desirably addressed and highly dense memory cells are desirably formed at a low cost.

To address the issues described above, a method of producing a semiconductor device according to a first aspect of the present invention is a method of producing a semiconductor device including a memory element configured to perform a data write operation, a data read operation, and a data erase operation by controlling voltages applied to a first gate conductor layer, a second gate conductor layer, a third gate conductor layer, a first impurity layer, a second impurity layer, and a third impurity layer, the method including forming a first semiconductor layer, a first insulating layer, a first gate material layer, a second insulating layer, and a second gate material layer on a substrate in a direction perpendicular to the substrate; forming a first material layer and a second material layer above the second gate material layer, the first material layer and the second material layer being separate from each other and adjacent to each other in a first direction in plan view; forming a third material layer that is continuous and surrounds side surfaces of the first material layer and the second material layer; forming a fourth material layer that is continuous and covers a side surface of the third material layer; etching the first material layer, the second material layer, the third material layer, the second gate material layer, the second insulating layer, the first gate material layer, and the first insulating layer using the fourth material layer as a mask to form a first hole extending in the first direction in plan view; forming a first gate insulating layer in the first hole to form a second hole and a third hole that are separate from each other by the first gate insulating layer; removing the first gate insulating layer at bottom portions of the second hole and the third hole; forming a first semiconductor pillar and a second semiconductor pillar respectively in the second hole and the third hole by deposition or crystal growth of semiconductor atoms; forming the first gate conductor layer and the second gate conductor layer that are divisional portions of the first gate material layer divided by the first gate insulating layer and forming the third gate conductor layer that is the second gate material layer, or forming the first gate conductor layer, the second gate conductor layer, and the third gate conductor layer by removing the first gate material layer and the second gate material layer and filling spaces caused by the removal; and forming the second impurity layer on the first semiconductor pillar and forming the third impurity layer on the second semiconductor pillar, wherein the first semiconductor layer is the first impurity layer.

According to a second aspect of the invention, in the method according to the first aspect of the invention, a distance between an outer periphery edge of the first material layer and an outer periphery edge of the second material layer on a center line of the first material layer and the second material layer arranged in the first direction may be set to be smaller than twice a thickness of the third material layer on a line passing through a center of the first material layer in a second direction orthogonal to the first direction, and the first gate insulating layer may be formed such that the second hole and the third hole separated from each other are formed.

According to a third aspect of the invention, in the method according to the first aspect of the invention, the first gate insulating layer may be formed such that a length between an outer periphery edge of the second hole and an outer periphery edge of the third hole that intersect with a center line passing through a center of the second hole and a center of the third hole in the first direction is smaller than twice a thickness of the first gate insulating layer on a line that passes through a center of the first material layer and is orthogonal to the first direction in plan view.

According to a fourth aspect of the invention, in the method according to the first aspect of the invention, the third gate conductor layer may be divided by the first hole to form a fifth gate conductor layer and a sixth gate conductor layer.

According to a fifth aspect of the invention, in the method according to the first aspect of the invention, a wiring connected to the first impurity layer may be a source line, a wiring connected to the second impurity layer may be a bit line, one of a wiring connected to the first or second gate conductor layer and a wiring connected to the third gate conductor layer may be connected to a plate line, and the other of the wiring connected to the first or second gate conductor layer and the wiring connected to the third gate conductor layer may be connected to a word line, and the data erase operation, the data read operation, and the data write operation may be performed based on voltages applied to the source line, the bit line, the plate line, and the word line.

According to a sixth aspect of the invention, the method according to the first aspect of the invention may further include forming a fourth hole that is parallel to the first hole extending in the first direction in plan view, the fourth hole being formed when the first hole is formed; forming, in the fourth hole, a second gate insulating layer, a third semiconductor pillar, and a fourth semiconductor pillar when the first gate insulating layer, the first semiconductor pillar, and the second semiconductor pillar are formed, the third semiconductor pillar and the fourth semiconductor pillar being isolated from each other by the second gate insulating layer; and forming a fourth impurity layer on the third semiconductor pillar and a fifth impurity layer on the fourth semiconductor pillar, in which the first hole and the fourth hole may be formed to be separate from each other in the second direction in plan view.

According to a seventh aspect of the invention, in the method according to the sixth aspect of the invention, one or both of the first gate conductor layer and the second gate conductor layer located between a row of the first and second semiconductor pillars and a row of the third and fourth semiconductor pillars may be formed to have two divisional portions and extend in the first direction in plan view.

According to an eighth aspect of the invention, in the method according to the sixth aspect of the invention, either the first gate conductor layer or the second gate conductor layer located between a row of the first and second semiconductor pillars and a row of the third and fourth semiconductor pillars may be continuous between the row of the first and second semiconductor pillars and the row of the third and fourth semiconductor pillars and extend in the first direction in plan view.

According to a ninth aspect of the invention, in the method according to the sixth aspect of the invention, the third gate conductor layer located between a row of the first and second semiconductor pillars and a row of the third and fourth semiconductor pillars may be formed to have two divisional portions and extend in the first direction in plan view.

According to a tenth aspect of the invention, the method according to the first aspect of the invention may further include removing the fourth material layer after forming the first semiconductor pillar and the second semiconductor pillar; forming a mask material layer surrounding an outer periphery portion of a top portion of the first semiconductor pillar and an outer peripheral portion of a top portion of the second semiconductor pillar; and etching the second gate material layer by using the mask material layer as a mask to form the third gate conductor layer.

According to an eleventh aspect of the invention, the method according to the tenth aspect of the invention may further include etching the second gate material layer, the first insulating layer, and the first gate material layer by using the mask material layer as a mask to form the first gate conductor layer, the second gate conductor layer, and the third gate conductor layer that has two divisional portions.

According to a twelfth aspect of the invention, the method according to the first aspect of the invention may further include after the forming of the first gate insulating layer in the first hole to form the second hole and the third hole that are separate from each other by the first gate insulating layer, forming a first protective film on an entire surface; removing the first protective film and the first gate insulating layer at the bottom portions of the second hole and the third hole by etching; and removing the remaining first protective film.

According to a thirteenth aspect of the invention, the method according to the first aspect of the invention may further include forming the first gate conductor layer, the second gate conductor layer, the third gate conductor layer, the first impurity layer, the second impurity layer, and the third impurity layer that enable the data write operation of holding, in one or both of the first semiconductor pillar and the second semiconductor pillar, a group of holes or a group of electrons that is a majority carrier of the first semiconductor pillar and the second semiconductor pillar and is generated by an impact ionization phenomenon or a gate-induced drain leakage current, by controlling voltages applied to the first gate conductor layer, the second gate conductor layer, the third gate conductor layer, the first impurity layer, the second impurity layer, and the third impurity layer and that enable the group of holes or the group of electrons that is the majority carrier of the first semiconductor pillar and the second semiconductor pillar to be discharged from one or both of the first semiconductor pillar and the second semiconductor pillar by controlling voltages applied to the first gate conductor layer, the second gate conductor layer, the first impurity layer, the second impurity layer, and the third impurity layer

### BRIEF DESCRIPTION OF THE DRAWINGS

FIGS. 1A and 1B are diagrams illustrating a structure of a dynamic flash memory cell according to a first embodiment;

FIGS. 2A to 2C are diagrams for describing a mechanism of an erase operation of the dynamic flash memory cell according to the first embodiment;

FIGS. 3A to 3C are diagrams for describing a mechanism of a write operation of the dynamic flash memory cell according to the first embodiment;

FIGS. 4AA to 4AC are diagrams for describing a mechanism of a read operation of the dynamic flash memory cell according to the first embodiment;

FIGS. 4BA to 4BD are diagrams for describing the mechanism of the read operation of the dynamic flash memory cell according to the first embodiment;

FIGS. 5AA to 5AC are diagrams for describing a method of producing a dynamic flash memory device according to the first embodiment;

FIGS. 5BA to 5BC are diagrams for describing the method of producing a dynamic flash memory device according to the first embodiment;

FIGS. 5CA to 5CC are diagrams for describing the method of producing a dynamic flash memory device according to the first embodiment;

FIGS. 5DA to 5DC are diagrams for describing the method of producing a dynamic flash memory device according to the first embodiment;

FIGS. 5EA to 5EC are diagrams for describing the method of producing a dynamic flash memory device according to the first embodiment;

FIGS. 5FA to 5FC are diagrams for describing the method of producing a dynamic flash memory device according to the first embodiment;

FIGS. 5GA to 5GC are diagrams for describing the method of producing a dynamic flash memory device according to the first embodiment;

FIGS. 5HA to 5HC are diagrams for describing the method of producing a dynamic flash memory device according to the first embodiment;

FIGS. 51A to 51C are diagrams for describing the method of producing a dynamic flash memory device according to the first embodiment;

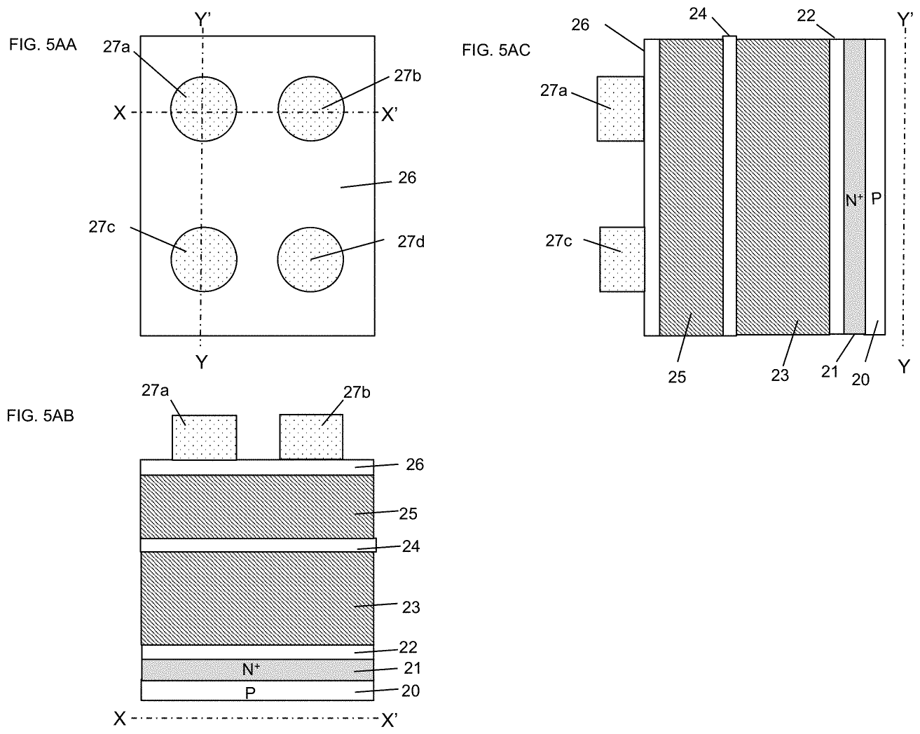

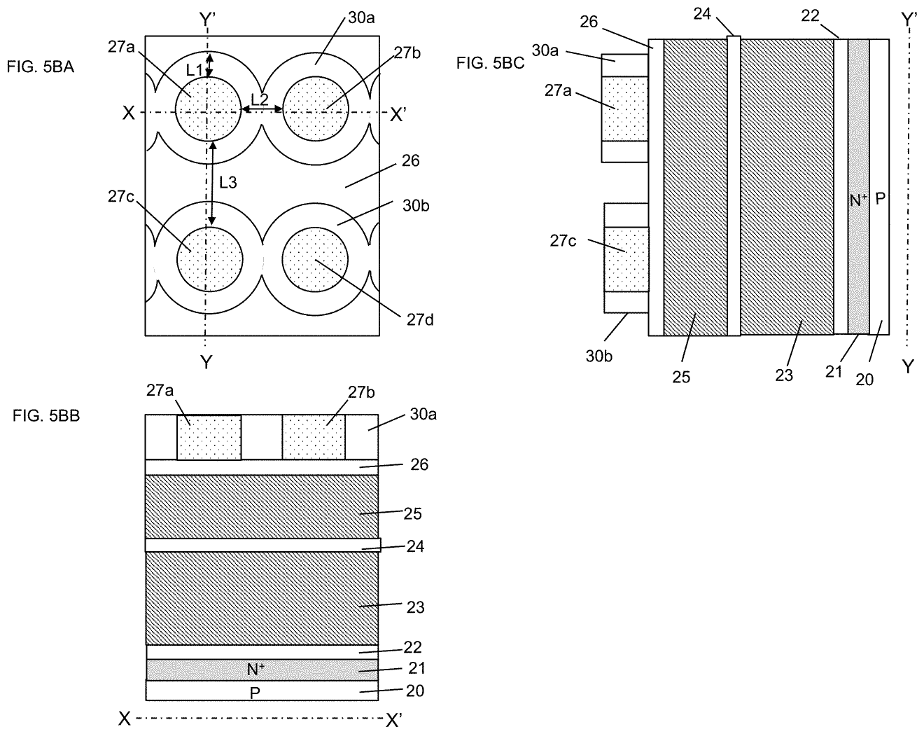

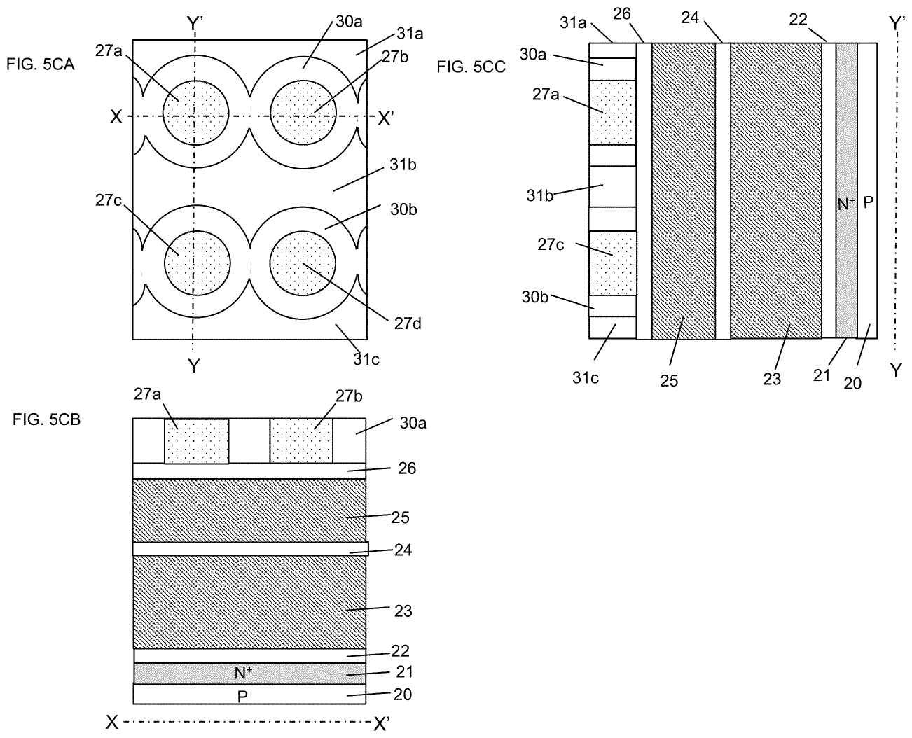

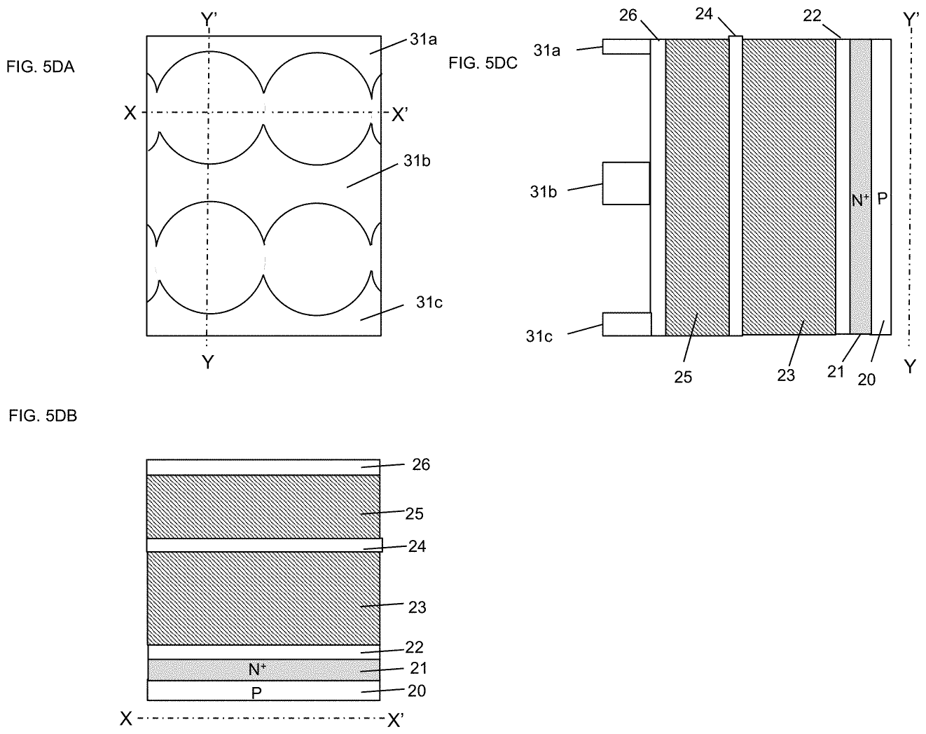

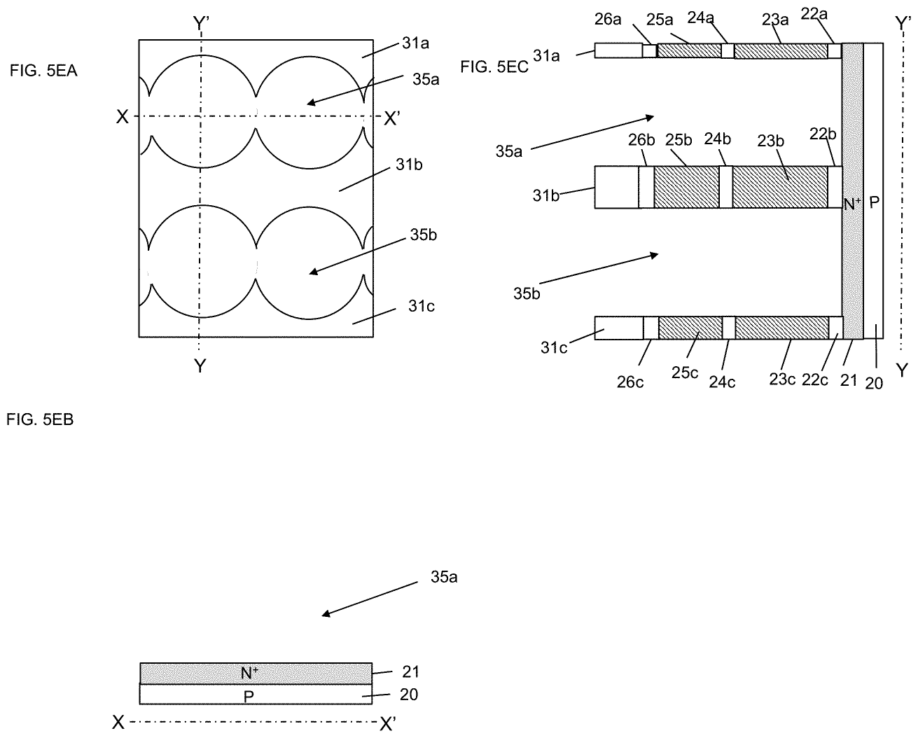

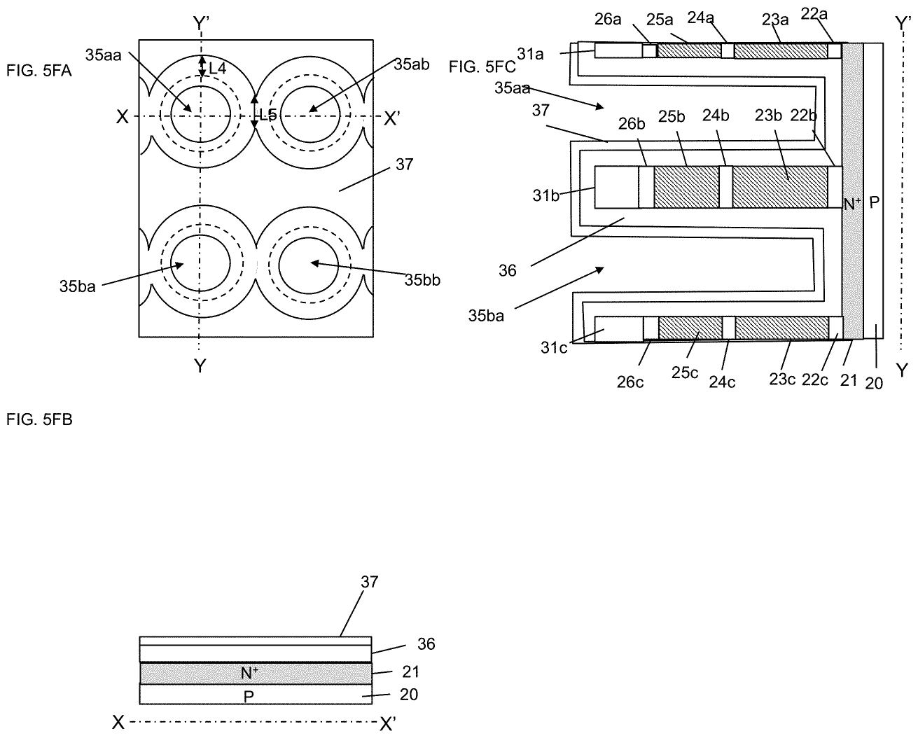

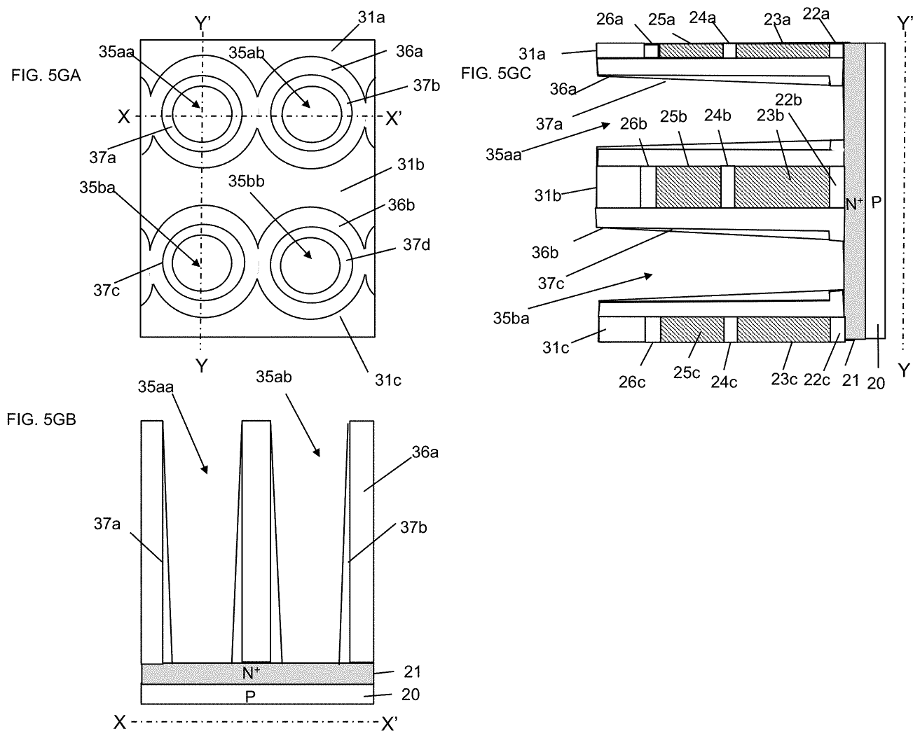

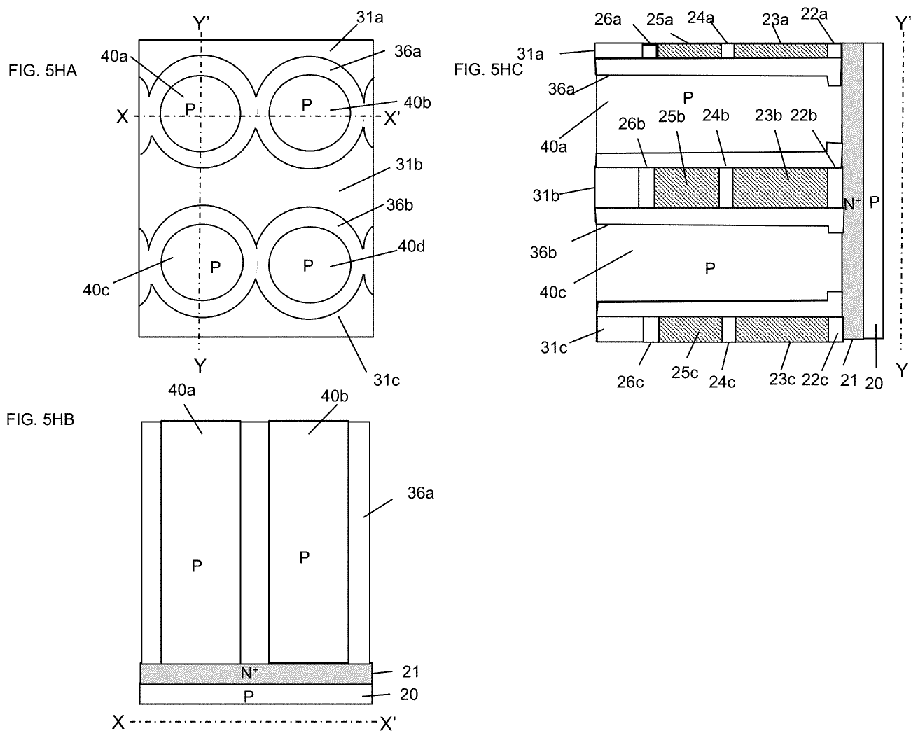

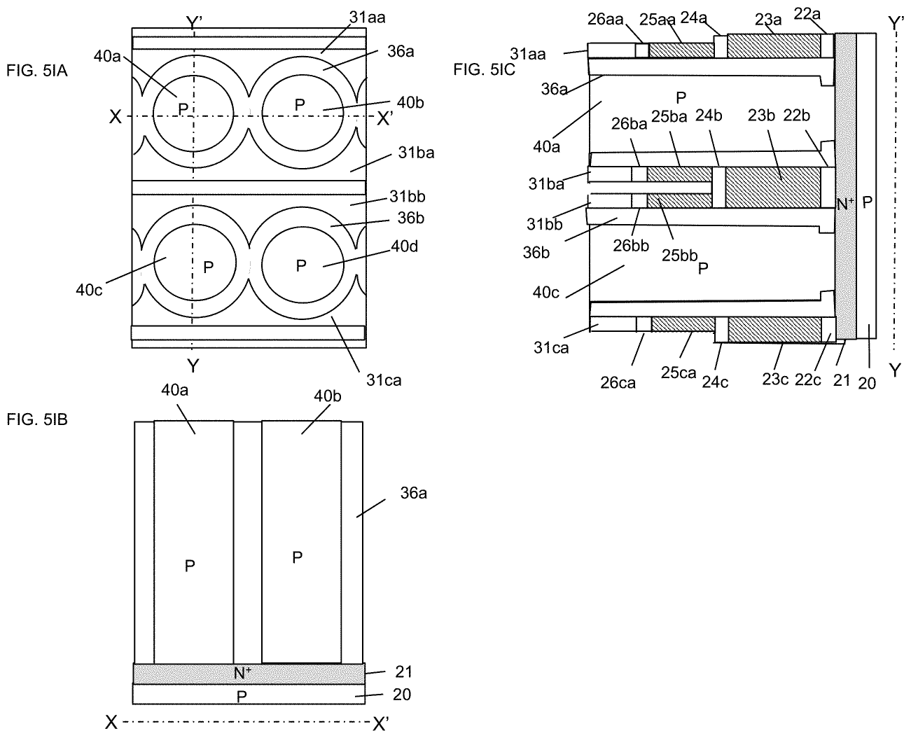

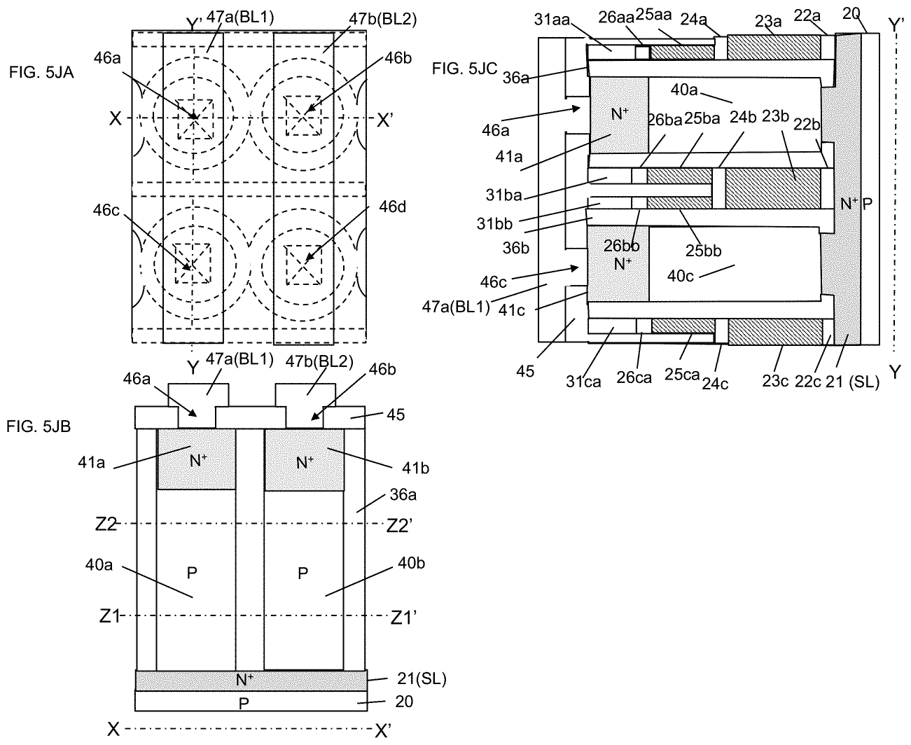

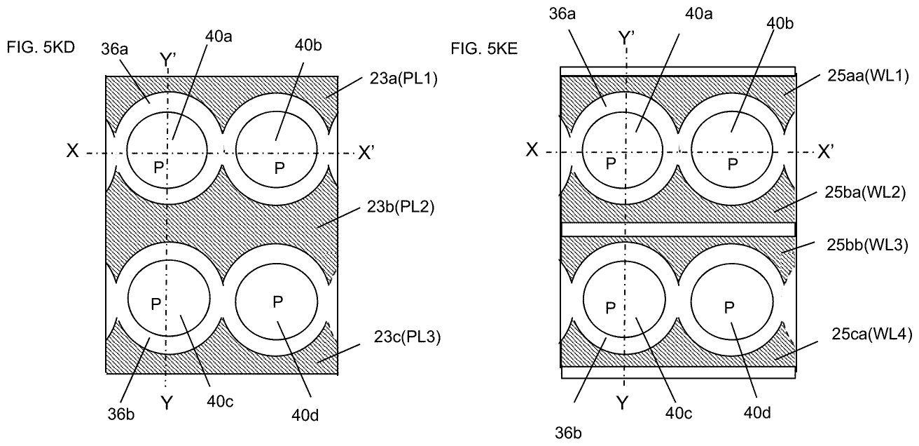

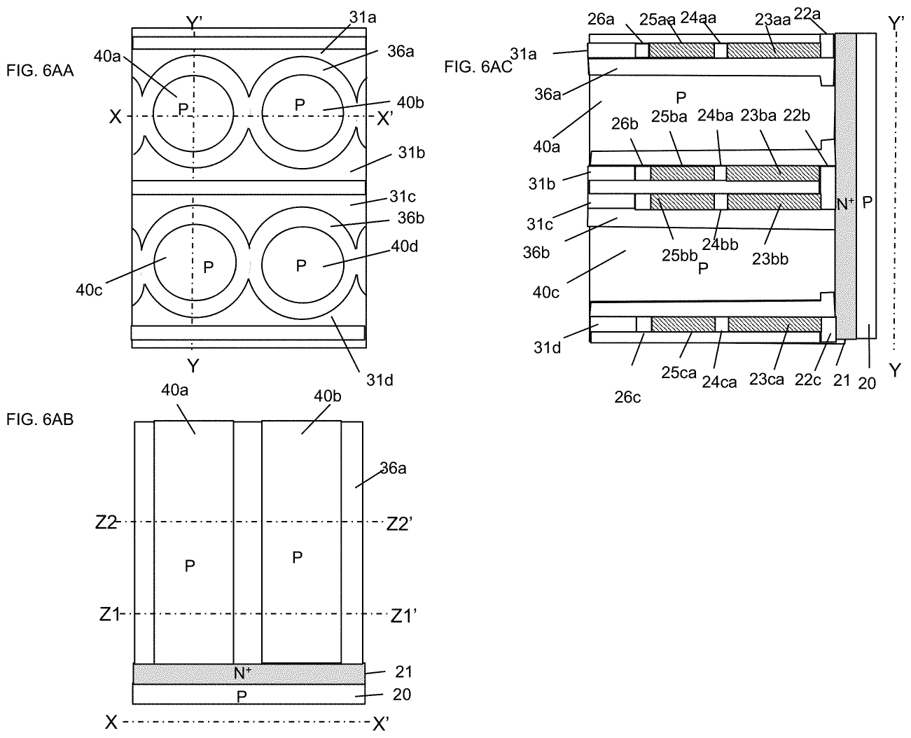

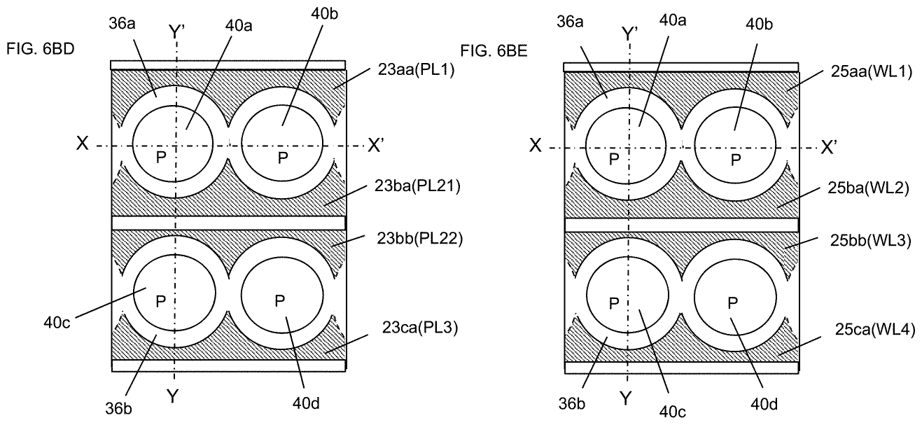

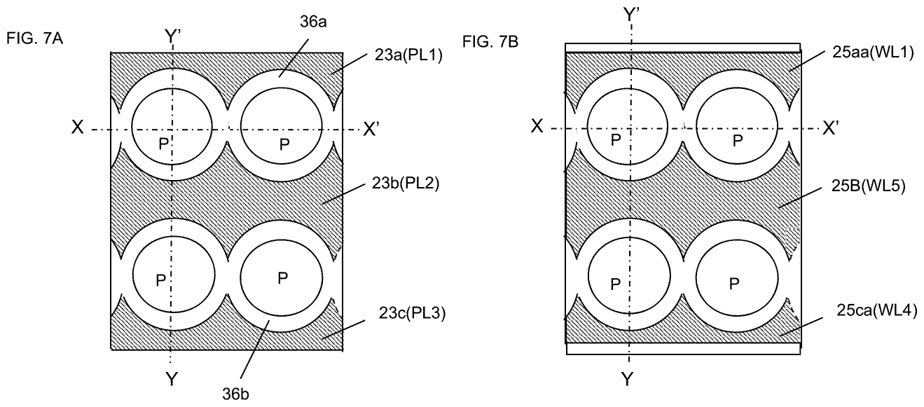

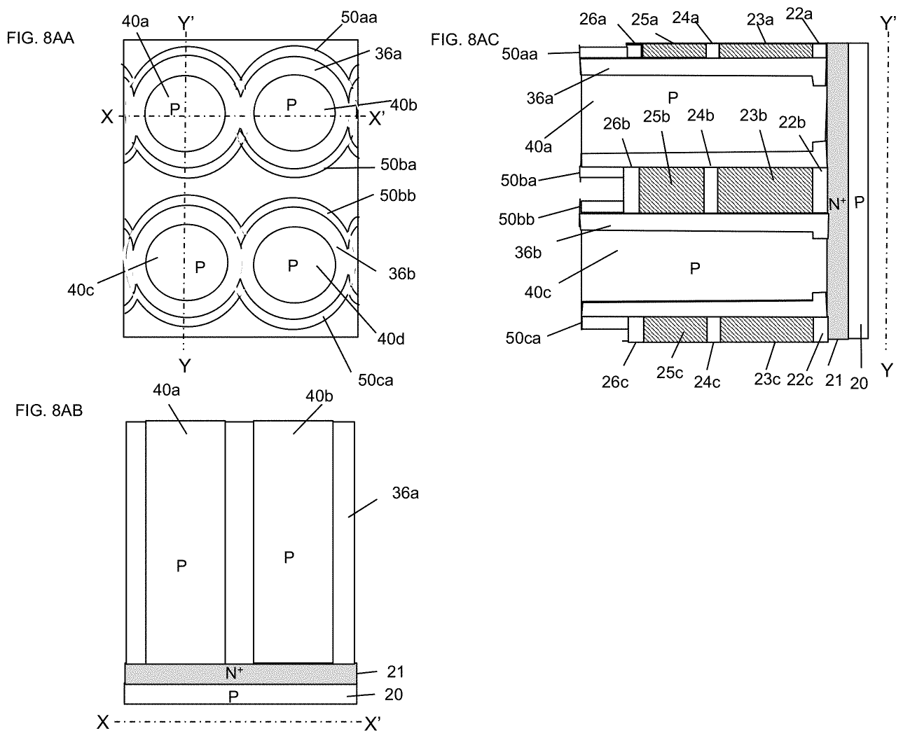

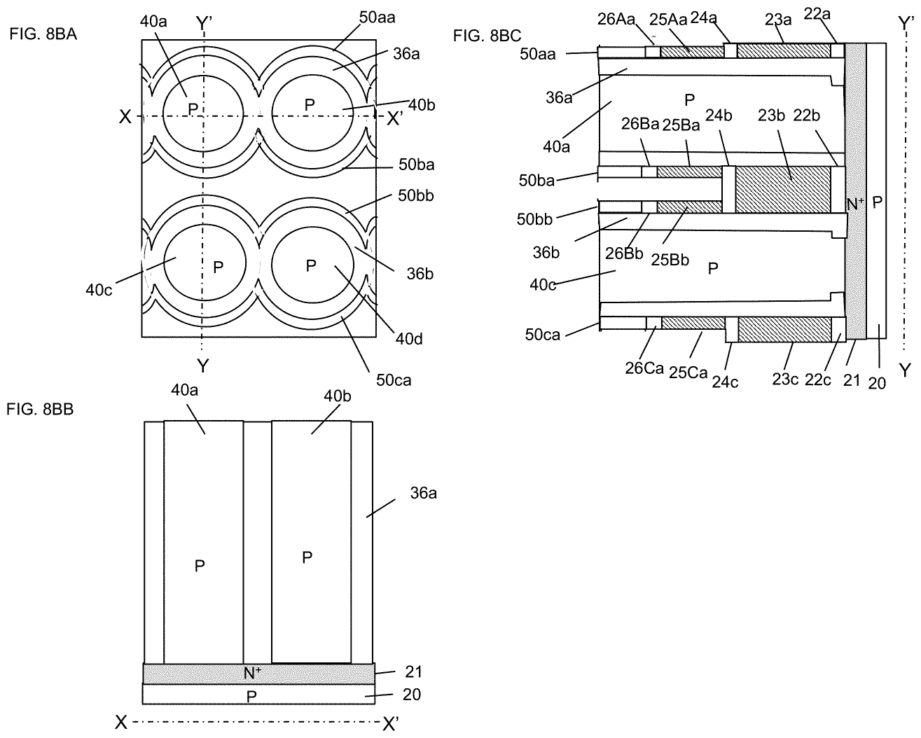

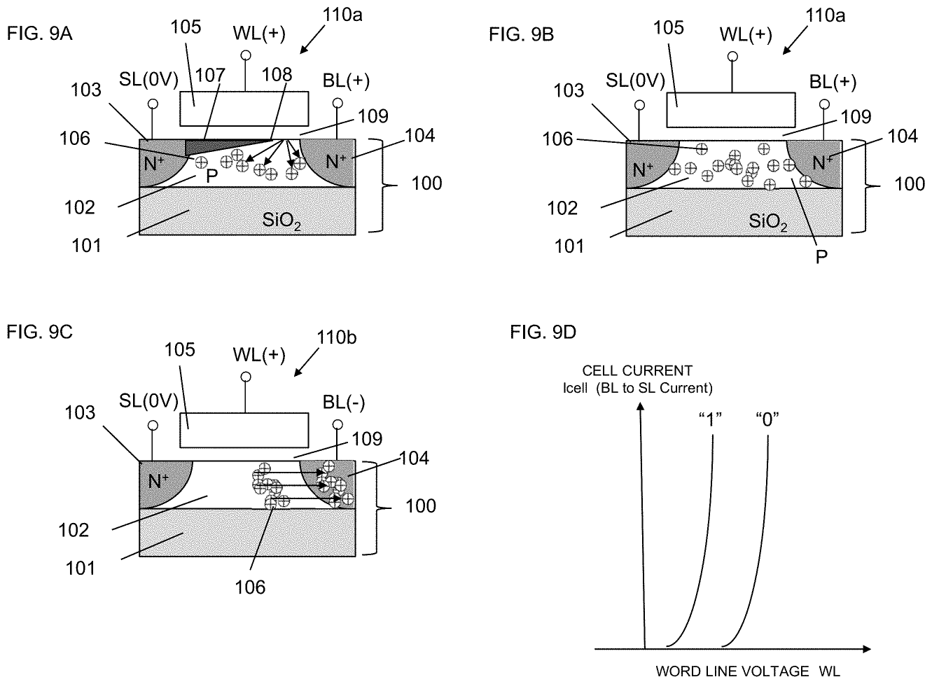

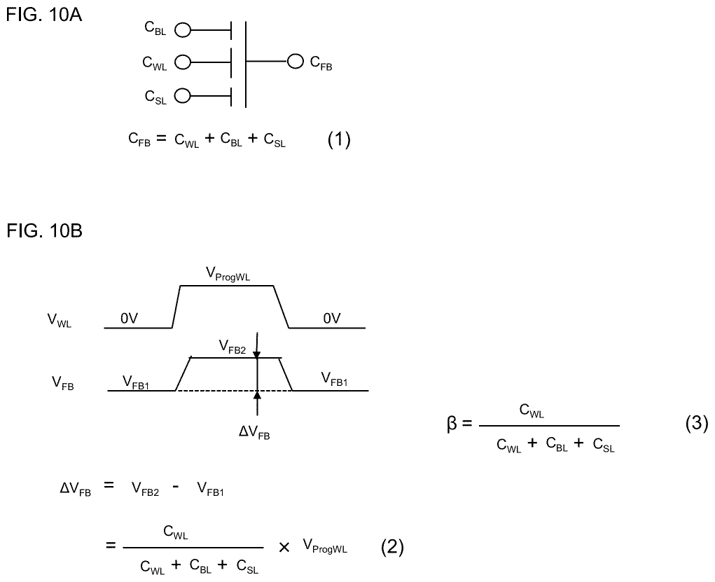

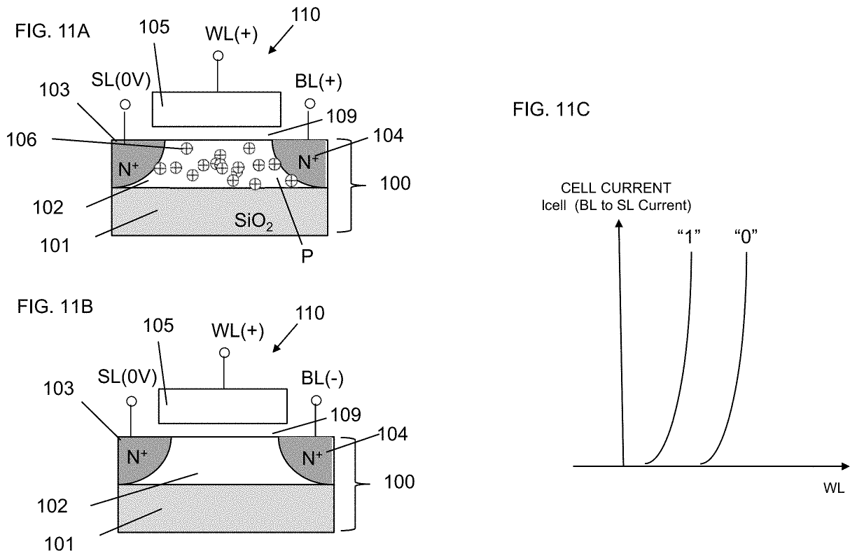

FIGS. 5JA to 5JC are diagrams for describing the method of producing a dynamic flash memory device according to the first embodiment;

FIGS. 5KD and 5KE are diagrams for describing the method of producing a dynamic flash memory device according to the first embodiment;

FIGS. 6AA to 6AC are diagrams for describing a method of producing a dynamic flash memory device according to a second embodiment;

FIGS. 6BD and 6BE are diagrams for describing a method of producing a dynamic flash memory device according to the second embodiment;

FIGS. 7A and 7B are diagrams for describing a method of producing a dynamic flash memory device according to a third embodiment;

FIGS. 8AA to 8AC are diagrams for describing a method of producing a dynamic flash memory device according to a fourth embodiment;

FIGS. 8BA to 8BC are diagrams for describing the method of producing a dynamic flash memory device according to the fourth embodiment;

FIGS. 9A to 9D are diagrams for describing a write operation of a capacitorless DRAM memory cell of the related art;

FIGS. 10A and 10B are diagrams for describing an issue in an operation of the capacitorless DRAM memory cell of the related art; and

FIGS. 11A to 11C are diagrams for describing an issue in the operation of the capacitorless DRAM memory cell of the related art.

### DETAILED DESCRIPTION OF THE PREFERRED EMBODIMENTS

Hereinafter, structures and operations of a memory device (hereinafter, referred to as a dynamic flash memory device), using a semiconductor element, according to embodiments of the present invention will be described with reference to the drawings.

### First Embodiment

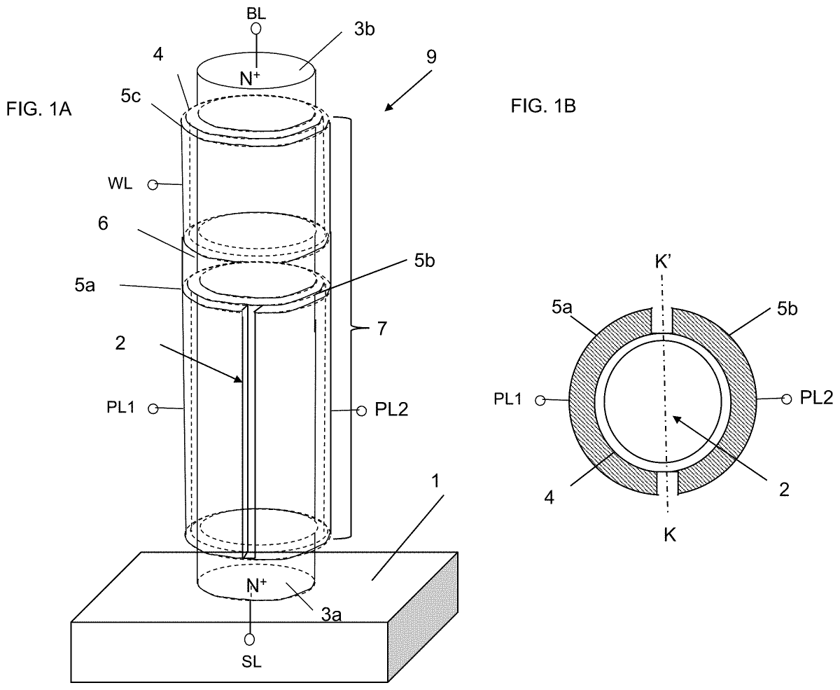

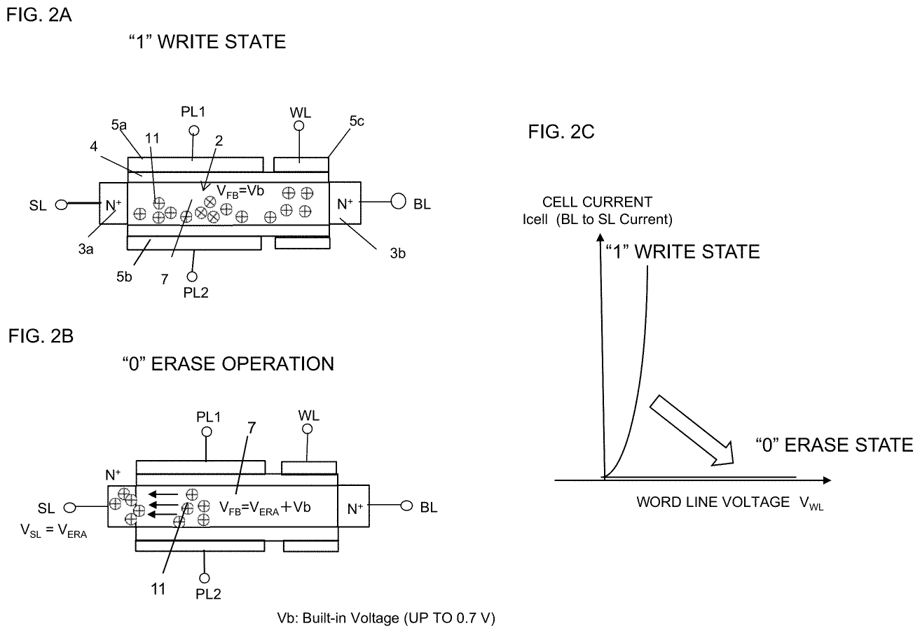

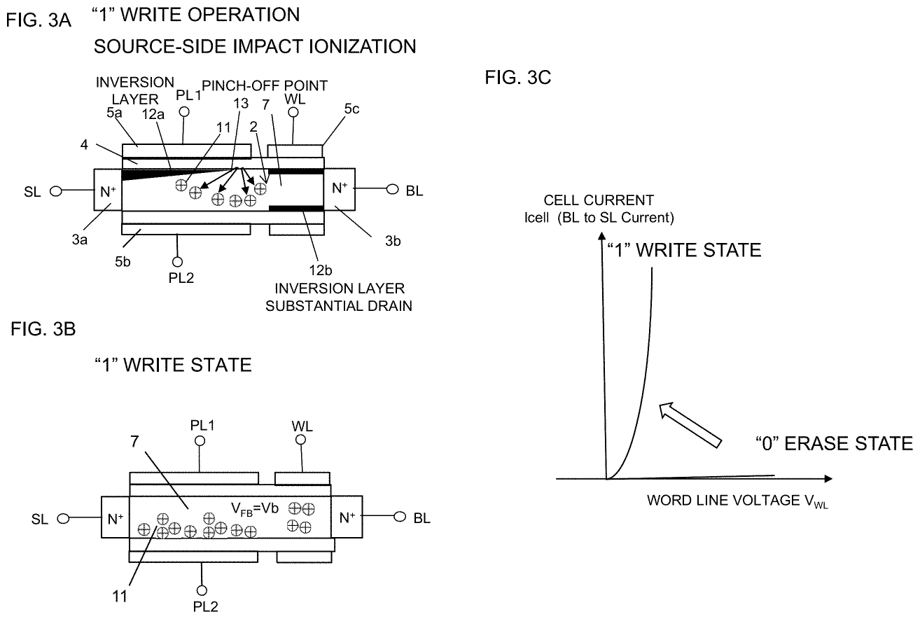

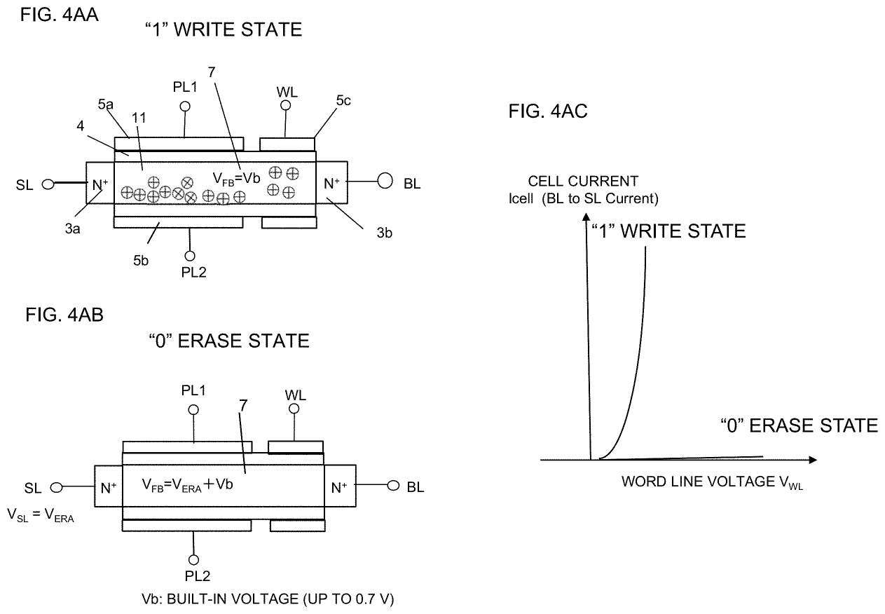

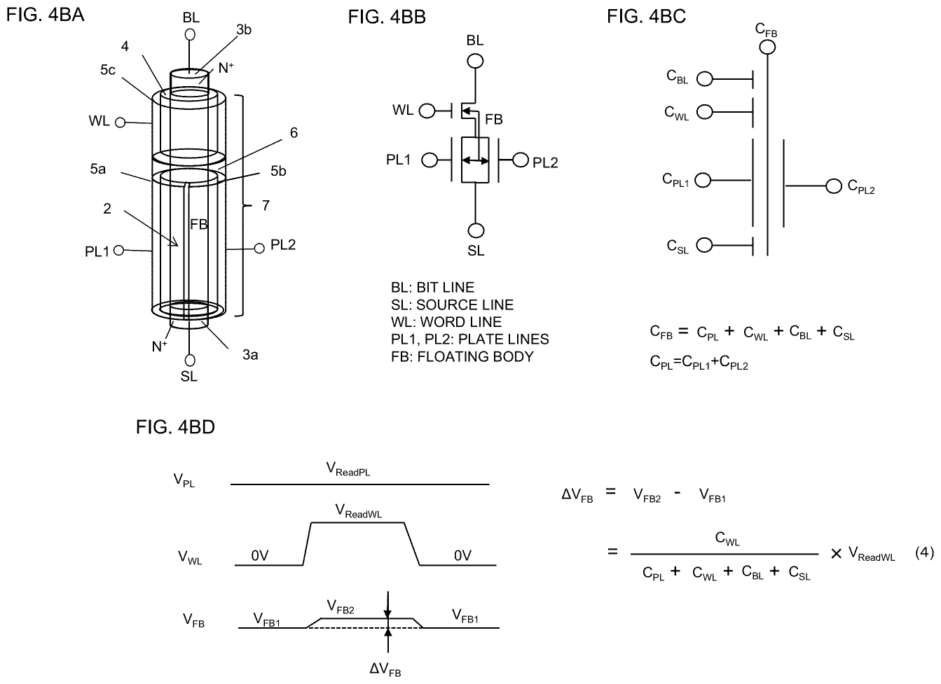

A structure and an operation mechanism of a dynamic flash memory cell according to a first embodiment of the present invention will be described with reference to FIGS. 1A to 5KE. The structure of the dynamic flash memory cell will be described with reference to FIGS. 1A and 1B. A data erase mechanism will be described with reference to FIGS. 2A to 2C. A data write mechanism will be described with reference to FIGS. 3A to 3C. A data read mechanism will be described with reference to FIGS. 4AA to 4BD. A production method of forming four dynamic flash memory cells on a substrate will be described with reference to FIGS. 5AA to 5KE.

FIGS. 1A and 1B illustrate the structure of the dynamic flash memory cell according to the first embodiment of the present invention. Specifically, FIG. 1A is a perspective view, and FIG. 1B is a horizontal cross-sectional view of a portion where a first gate conductor layer 5a (described later) and a second gate conductor layer 5b (described later) are present. As illustrated in FIG. 1A, a silicon pillar 2 (hereinafter referred to as a “Si pillar”) having a conductivity type of p-type or i-type (intrinsic type) is on a substrate 1. A bottom portion of the Si pillar 2 is connected to an N⁺ layer 3a. A top portion of the Si pillar 2 is connected to an N⁺ layer 3b. One of the N⁺ layers 3a and 3b serves as a source, and the other of the N⁺ layers 3a and 3b serves as a drain. The Si pillar 2 between the N⁺ layer 3a and the N⁺ layer 3b serves as a channel region 7. The Si pillar 2 is surrounded by a gate insulating layer 4. The gate insulating layer 4 is in contact with or in proximity to the N⁺ layers 3a and 3b serving as the source and the drain. A lower portion of the gate insulating layer 4 is surrounded by the first gate conductor layer 5a and the second gate conductor layer 5b. As illustrated in FIG. 1B, the first gate conductor layer 5a and the second gate conductor layer 5b are isolated from each other around the gate insulating layer 4. An upper portion of the gate insulating layer 4 is surrounded by a third gate conductor layer 5c. The first gate conductor layer 5a and the third gate conductor layer 5c are isolated from each other by an insulating layer 6. The second gate conductor layer 5b and the third gate conductor layer 5c are isolated from each other by the insulating layer 6. In this manner, a dynamic flash memory cell 9 including the N⁺ layers 3a and 3b serving as the source and the drain, the channel region 7, the gate insulating layer 4, the first gate conductor layer 5a, the second gate conductor layer 5b, and the third gate conductor layer 5c is formed. The N⁺ layer 3a is connected to a source line SL. The N⁺ layer 3b is connected to a bit line BL. The first gate conductor layer 5a is connected to a first plate line PL1. The second gate conductor layer 5b is connected to a second plate line PL2. The third gate conductor layer 5c is connected to a word line WL. In an actual dynamic flash memory device, a plurality of memory cells described above are two-dimensionally arranged on the substrate 1.

The third gate conductor layer 5c connected to the word line WL may be divided into two portions, similarly to the first gate conductor layer 5a connected to the first plate line PL1 and the second gate conductor layer 5b connected to the second plate line PL2.

The substrate 1 may be an SOI substrate or a single-layer or multilayer substrate of Si or another semiconductor material. The substrate 1 may be a single-layer or multilayer well layer of an N-layer or P-layer Si pillar. In FIG. 1B, the first gate conductor layer 5a and the second gate conductor layer 5b have an equal length (outer peripheral length) in a circumferential direction in which the first gate conductor layer 5a and the second gate conductor layer 5b surround the gate insulating layer 4 but may have different outer peripheral lengths.

A mechanism of an erase operation will be described with reference to FIGS. 2A to 2C. The channel region 7 between the N⁺ layer 3a and the N⁺ layer 3b is electrically isolated from the substrate 1 and thus is a floating body. FIG. 2A illustrates the channel region 7 in which a group of holes 11 generated by impact ionization in the previous cycle is accumulated before an erase operation. A voltage of the second plate line PL2 is set be lower than a voltage of the first plate line PL1, so that the group of holes 11 is accumulated in a portion of the channel region 7 closer to the second gate conductor layer 5b connected to the second plate line PL2. As illustrated in FIG. 2B, during the erase operation, a voltage of the source line SL is set to a negative voltage V_{ERA}. For example, V_{ERA} is equal to −3 V. As a result, regardless of the value of the initial potential of the channel region 7, a PN junction between the channel region 7 and the N⁺ layer 3a serving as the source connected to the source line SL is forward biased. As a result, the group of holes 11 generated by impact ionization in the previous cycle and accumulated in the channel region 7 is drawn into the N⁺ layer 3a serving as the source, and the potential V_{FB} of the channel region 7 becomes V_{FB}=V_{ERA}+Vb. Here, Vb denotes a built-in voltage of the PN junction and is about 0.7 V. Thus, in the case of V_{ERA}=−3 V, the potential V_{FB} of the channel region 7 is equal to −2.3 V. This value corresponds to a potential state of the channel region 7 in an erase state. Thus, when the potential of the channel region 7 that is the floating body becomes a negative voltage, a threshold voltage of an N-channel MOS transistor of the dynamic flash memory cell 9 increases because of a substrate bias effect. Thus, as illustrated in FIG. 2C, the threshold voltage of the third gate conductor layer 5c to which the word line WL is connected increases. This erase state of the channel region 7 is assigned to logical storage data “0”. In data reading, the voltage applied to the first gate conductor layer 5a connected to the first plate line PL1 is set to be higher than the threshold voltage at the time of logical storage data “1” and to be lower than the threshold voltage at the time of logical storage data “0”. Consequently, a characteristic that no current flows even if the voltage of the word line WL is increased in reading of the logical storage data “0” is obtained as illustrated in FIG. 2C. For example, the erase operation may be performed by applying a voltage difference between the bit line BL and the source line SL. The above-described conditions of the voltages applied to the bit line BL, the source line SL, the word line WL, the first plate line PL1, and the second plate line PL2 are an example for performing the erase operation, and may be other operation conditions under which the erase operation can be performed.

FIGS. 3A to 3C illustrate a write operation of the dynamic flash memory cell according to the first embodiment of the present invention. As illustrated in FIG. 3A, for example, 0 V is input to the N⁺ layer 3a to which the source line SL is connected. For example, 3 V is input to the N⁺ layer 3b to which the bit line BL is connected. For example, 2 V is input to the first gate conductor layer 5a to which the first plate line PL1 is connected. For example, 0 V is input to the second gate conductor layer 5b to which the second plate line PL2 is connected. For example, 5 V is input to the third gate conductor layer 5c to which the word line WL is connected. As a result, as illustrated in FIG. 3A, an inversion layer 12a is formed in a region on the inner side relative to the first gate conductor layer 5a to which to the first plate line PL1 is connected, and a first N-channel MOS transistor region which is the channel region 7 surrounded by the first gate conductor layer 5a is operated in a saturated region. As a result, the inversion layer 12a in the region on the inner side relative to the first gate conductor layer 5a connected to the first plate line PL1 has a pinch-off point 13. On the other hand, a second N-channel MOS transistor region which is the channel region 7 surrounded by the third gate conductor layer 5c connected to the word line WL is operated in a linear region. As a result, an inversion layer 12b not having the pinch-off point is formed in the entire region on the inner side relative to the third gate conductor layer 5c to which the word line WL is connected. The inversion layer 12b formed in the entire region on the inner side relative to the third gate conductor layer 5c to which the word line WL is connected functions as a substantial drain of the first N-channel MOS transistor region having the first gate conductor layer 5a. As a result, the electric field becomes maximum in a boundary region (first boundary region) of the channel region 7 between the first N-channel MOS transistor region having the first gate conductor layer 5a and the second N-channel MOS transistor region having the third gate conductor layer 5c that are connected in series, and an impact ionization phenomenon occurs in this region. Electrons flow from the N⁺ layer 3a connected to the source line SL toward the N⁺ layer 3b connected to the bit line BL. The accelerated electrons collide with lattice Si atoms, and electron-hole pairs are generated by the kinetic energy of the collision. Most of the generated electrons flow to the N⁺ layer 3b connected to the bit line BL. In writing of “1”, a gate-induced drain leakage (GIDL) current may be used to generate electron-hole pairs (see E. Yoshida and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-697, April 2006), and the floating body FB may be filled with the generated group of holes.

As illustrated in FIG. 3B, the generated group of holes 11 is the majority carrier of the channel region 7, and charges the channel region 7 to a positive bias. Since the N⁺ layer 3a connected to the source line SL has 0 V, the channel region 7 is charged up to the built-in voltage Vb (about 0.7 V) of the PN junction between the channel region 7 and the N⁺ layer 3a connected to the source line SL. When the channel region 7 is charged to a positive bias, the threshold voltages of the first N-channel MOS transistor region and the second N-channel MOS transistor region decrease because of the substrate bias effect. Thus, as illustrated in FIG. 3C, the threshold voltage of the N-channel MOS transistor of a second channel region 7b to which the word line WL is connected decreases. This write state of the channel region 7 is assigned to logical storage data “1”.

In the write operation, electron-hole pairs may be generated by an impact ionization phenomenon or a GIDL current in the boundary region between the N⁺ layer 3a and the channel region 7 or in the boundary region between the N⁺ layer 3b and the channel region 7, and the channel region 7 may be charged with the generated group of holes 11. The above-described conditions of the voltages applied to the bit line BL, the source line SL, the word line WL, the first plate line PL1, and the second plate line PL2 are an example for performing the write operation, and may be other operation conditions under which the write operation can be performed.

A read operation of the dynamic flash memory cell according to the first embodiment of the present invention and a memory cell structure related to the read operation will be described with reference to FIGS. 4AA to 4AC and 4BA to 4BD. The read operation of the dynamic flash memory cell will be described with reference to FIGS. 4AA to 4AC. As illustrated in FIG. 4AA, when the channel region 7 is charged up to the built-in voltage Vb (about 0.7 V), the threshold voltage of the N-channel MOS transistor decreases because of the substrate bias effect. This state is assigned to logical storage data “1”. As illustrated in FIG. 4AB, when a memory block to be selected before writing is in the erase state “0” in advance, the floating voltage V_{FB} of the channel region 7 is equal to V_{ERA}+Vb. The write state “1” is stored at random through the write operation. As a result, logical storage data of logical “0” and logical “1” is created for the word line WL. As illustrated in FIG. 4AC, reading is performed by a sense amplifier using a level difference between the two threshold voltages for this word line WL.

With reference to FIGS. 4BA to 4BD, a relationship among three gate capacitances of the first gate conductor layer 5a, the second gate conductor layer 5b, and the third gate conductor layer 5c during the read operation of the dynamic flash memory cell according to the first embodiment of the present invention and an operation related thereto will be described. The gate capacitance of the third gate conductor layer 5c connected to the word line WL is desirably designed to be smaller than a total gate capacitance of the capacitance of the first gate conductor layer 5a connected to the first plate line PL1 and the capacitance of the second gate conductor layer 5b connected to the second plate line PL2. As illustrated in FIG. 4BA, vertical-direction lengths of the first gate conductor layer 5a connected to the first plate line PL1 and the second gate conductor layer 5b connected to the second plate line PL2 are set to be longer than a vertical-direction length of the third gate conductor layer 5c connected to the word line WL to make the gate capacitance of the third gate conductor layer 5c connected to the word line WL smaller than the total gate capacitance of the capacitance of the first gate conductor layer 5a connected to the first plate line PL1 and the capacitance of the second gate conductor layer 5b connected to the second plate line PL2. FIG. 4BB illustrates an equivalent circuit of the single dynamic flash memory cell illustrated in FIG. 4BA. FIG. 4BC illustrates a relationship among coupling capacitances in the dynamic flash memory cell. C_{WL} denotes a capacitance of the third gate conductor layer 5c. C_{PL} denotes a total capacitance of a capacitance C_{PL1} of the first gate conductor layer 5a and a capacitance C_{PL2} of the second gate conductor layer 5b. C_{BL} denotes a capacitance of the PN junction between the second channel region 7b and the N⁺ layer 3b serving as the drain. C_{SL} denotes a capacitance of the PN junction between a first channel region 7a and the N⁺ layer 3a serving as the source. As illustrated in FIG. 4BD, when the voltage of the word line WL changes, the change affects the channel region 7 as noise. A potential change ΔV_{FB} of the channel region 7 at this time is denoted by

ΔV_{FB}=C_{WL}(C_{PL}+C_{WL}+C_{BL}+C_{SL})×V_{ReadWL} (4).

Here, V_{ReadWL} denotes the potential at the word line WL changed at the time of reading. As is apparent from Equation (4), if the contribution ratio of C_{WL} is made smaller than that of the total capacitance C_{PL}+C_{WL}+C_{BL}+C_{SL} of the entire channel region 7, ΔV_{FB} decreases. C_{BL}+C_{SL} denotes the capacitances of the PN junctions. To increase C_{BL}+C_{SL}, the diameter of the Si pillar 2 is increased, for example. In addition, if axial-direction lengths of the first gate conductor layer 5a connected to the first plate line PL1 and the second gate conductor layer 5b connected to the second plate line PL2 are made longer than an axial-direction length of the third gate conductor layer 5c connected to the word lines WL, ΔV_{FB} can be further decreased without reducing the degree of integration of the memory cells in plan view. The above-described conditions of the voltages applied to the bit line BL, the source line SL, the word line WL, the first plate line PL1, and the second plate line PL2 are an example for performing the read operation, and may be other operation conditions under which the read operation can be performed. This read operation may be performed using a bipolar operation.

When the third gate conductor layer 5c connected to the word line WL is divided into two gate conductor layers, these two gate conductor layers may be driven by applying synchronous or asynchronous voltages.

FIGS. 5AA to 5KE illustrate a method of producing a memory device including four dynamic flash memory cells according to the first embodiment formed on a substrate 20. FIGS. 5AA, 5BA, 5CA, 5DA, 5EA, 5FA, 5GA, 5HA, 5IA, and 5JA are plan views. FIGS. 5AB, 5BB, 5CB, 5DB, 5EB, 5FB, 5GB, 5HB, SIB, and 5JB are vertical sectional views taken along line X-X′ in FIGS. 5AA, 5BA, 5CA, 5DA, 5EA, 5FA, 5GA, 5HA, 5IA, and 5JA, respectively. FIGS. 5AC, 5BC, 5CC, 5DC, 5EC, 5FC, 5GC, 5HC, 5IC, and 5JC are vertical sectional views taken along line Y-Y′ in FIGS. 5AA, 5BA, 5CA, 5DA, 5EA, 5FA, 5GA, 5HA, 5IA, and 5JA, respectively. In an actual memory device, more than four dynamic flash memory cells are arranged in a matrix shape.

As illustrated in 5AA to 5AC, on the P-layer substrate 20 (which is an example of a “substrate” in the claims), an N⁺ layer 21 (which is an example of a “first semiconductor layer” in the claims), a SiO₂ layer 22 (which is an example of a “first insulating layer” in the claims), a poly-Si layer 23 (which is an example of a “first gate material layer” in the claims) containing a donor or acceptor impurity, a SiO₂ layer 24 (which is an example of a “second insulating layer” in the claims), a poly-Si layer 25 (which is an example of a “second gate material layer” in the claims) containing a donor or acceptor impurity, and an SiO₂ layer 26 are formed sequentially from the bottom. Hereinafter, a poly-Si layer containing a donor or acceptor impurity at a high concentration is referred to as a “poly-Si layer”. An insulating material layer 27a (which is an example of a “first material layer” in the claims), an insulating material layer 27b (which is an example of a “second material layer” in the claims), an insulating material layer 27c, and an insulating material layer 27d that have a circular shape in plan view are formed on the SiO₂ layer 26.

Next, as illustrated in FIGS. 5BA to 5BC, a silicon nitride layer (hereinafter, referred to as a SiN layer) (not illustrated) is deposited on the entire surface, and then the SiN layer is etched by a reactive ion etching (RIE) method to form a SiN layer 30a (which is an example of a “third material layer” in the claims) that is continuous and surrounds side surfaces of the insulating material layers 27a and 27b and a SiN layer 30b that is continuous and surrounds side surfaces of the insulating material layers 27c and 27d. For example, when the separate first material layer 27a is present, the SiN layer 30a is formed to have an equal width L1 in plan view. A length L2 between intersections where outer periphery edges of the insulating material layers 27a and 27b intersect with the line X-X′ is set to be smaller than twice the width L1, so that the SiN layer 30a that is continuous and surrounds the side surfaces of the insulating material layers 27a and 27b is formed. A length L3 between intersections where outer periphery edges of the insulating material layers 27a and 27c intersect with the line Y-Y′ is set to be larger than twice the width L1, the SiN layer 30a and the SiN layer 30b can be formed to be separate from each other.

Next, as illustrated in FIGS. 5CA to 5CC, an insulating layer (not illustrated) is deposited and is then polished by a chemical mechanical polishing (CMP) method such that the upper surface of the insulating layer is at the position of the upper surfaces of the insulating material layers 27a to 27d, so that mask material layers 31a, 31b, and 31c are formed. A combination of the mask material layers 31a and 31b is an example of a “fourth material layer” in the claims. The mask material layers 31a, 31b, and 31c are isolated from each other by the SiN layers 30a and 30b.

Next, as illustrated in FIGS. 5DA to 5DC, the insulating material layers 27a, 27b, 27c, and 27d and the SiN layers 30a and 30b are removed by etching using the mask material layers 31a, 31b, and 31c as masks.

Next, as illustrated in FIGS. 5EA to 5EC, the SiO₂ layer 26, the poly-Si layer 25, the SiO₂ layer 24, the poly-Si layer 23, and the SiO₂ layer 22 are etched by using the mask material layers 31a, 31b, and 31c as masks, to form SiO₂ layers 22a, 22b, and 22c, poly-Si layers 23a, 23b, and 23c, SiO₂ layers 24a, 24b, and 24c, poly-Si layers 25a, 25b, and 25c, and SiO₂ layers 26a, 26a, and 26c. Consequently, a hole 35a (an example of a “first hole” in the claims) and a hole 35b each of which is continuous in the X-X′ line direction in plan view are formed.

Next, as illustrated in FIGS. 5FA to 5FC, the entire surface is covered with a gate insulating layer 36. Then, the entire surface is covered with a protective layer 37. The gate insulating layer 36 and the protective layer 37 are formed using an atomic layer deposition (ALD) method. Since the ALD method enables deposition of material atoms in units of the atomic layers, inner surfaces of the holes 35a and 35b can be uniformly covered with the gate insulating layer 36 and the protective layer 37. Thus, a thickness L4 of the covering gate insulating layer 36 is set to be larger than one-half a shortest distance L5 of the hole 35a in the Y-Y′ line direction, so that a hole 35aa (which is an example of a “second hole” in the claims), a hole 35ab (which is an example of a “third hole” in the claims), a hole 35ba, and a hole 35bb that are isolated from one another in plan view are formed.

Next, as illustrated in FIGS. 5GA to 5GC, the protective layer 37 and the gate insulating layer 36 at bottom portions of the holes 35aa to 35bb are removed using the RIE method. Consequently, gate insulating layer 36a and 36b are formed on side surfaces of the holes 35aa to 35bb. This RIE etching is performed such that protective layers 37a, 37b, 37c, and 37d remain on side surfaces of the gate insulating layer 36a (which is an example of the “first gate insulating layer” in the claims) and the gate insulating layer 36b on the inner surfaces of the holes 35aa to 35bb.

Next, as illustrated in FIGS. 5HA to 5HC, after the protective layers 37a to 37d are removed, the holes 35aa to 35bb are filled to form a P-layer Si pillar 40a (which is an example of a “first semiconductor pillar”), a P-layer Si pillar 40b (which is an example of a “second semiconductor pillar”), a P-layer Si pillar 40c, and a P-layer Si pillar 40d. The P-layer Si pillars 40a, 40b, 40c, and 40d are formed using an epitaxial crystal growth method, a method of growing crystal from the upper portions of the holes 35aa to 35b, a molecular beam growth method, the ALD method, or the like. The gate insulating layers 36a and 36b may be formed by etching the gate insulating layer 36 at the bottom portions of the holes 35aa to 35bb by the RIE without forming the protective layers 37 and 37a to 37d.

Next, as illustrated in FIGS. 5IA to 5IC, poly-Si layers 25aa and 25ba that surround the gate insulating layer 36a, are isolated from each other, and extend in the X-X′ line direction in plan view are formed using a lithography method and the RIE method. Likewise, poly-Si layers 25bb and 25ca that surround the gate insulating layer 36b, are isolated from each other, and extend in the X-X′ line direction in plan view are formed. The poly-Si layers 25aa, 25ba, 25bb, and 25ca are formed by using mask material layers 31aa, 31ba, 31bb, and 31ca as etching masks, respectively. At the same time, the SiO₂ layer 26a, 26b, and 26c are etched by using the mask material layers 31aa, 31ba, 31bb, and 31ca as etching masks, so that SiO₂ layers 26aa, 26ba, 26bb, and 26ca are formed. Then, the poly-Si layers 25aa, 25ba, 25bb, and 25ca may be removed by etching, and new gate conductor layers may be formed again.

Next, as illustrated in FIGS. 5JA to 5JC, an N⁺ layer 41a (which is an example of a “second impurity layer” in the claims), an N⁺ layer 41b (which is an example of a “third impurity layer” in the claims), an N⁺ layer 41c, and an N⁺ layer 41d (not illustrated) are formed on top portions of the P-layer Si pillars 40a to 40d, respectively. Then, a SiO₂ layer 45 is formed to cover the entire surface. Then, contact holes 46a, 46b, 46c, and 46d are formed in the SiO₂ layer 45 on the N⁺ layers 41a to 41d, respectively. Then, a metal wiring layer 47a that is connected to the N⁺ layers 41a and 41c through the contact holes 46a and 46c, respectively, and extends in the Y-Y′ line direction is formed. Likewise, a metal wiring layer 47b that is connected to the N⁺ layers 41b and 41d through the contact holes 46b and 46d, respectively, and extends in the Y-Y′ line direction is formed. The N⁺ layer 21 is connected to the source line SL, and the metal wiring layers 47a and 47b are respectively connected to bit lines BL1 and BL2. The N⁺ layers 41a to 41d may be formed by etching the top portions of the P-layer Si pillars 40a to 40d and applying the epitaxial crystal growth method thereto. Alternatively, the N⁺ layers 41a to 41d may be formed using another method such as an ion implantation method. The position of the upper surface of the N⁺ layer 21 at the bottom portions of the P-layer Si pillars 40a to 40d is higher because of the thermal history after the formation of the P-layer Si pillars 40a to 40d illustrated in FIGS. 5HA to 5HC.

FIGS. 5KD and 5KE are plan views of cross-sections taken along line Z1-Z1′ and line Z2-Z2′ in FIG. 5JB, respectively. FIG. 5KD is a plan view of the cross-section taken along the line Z1-Z1′. FIG. 5KE is a plan view of the cross-section taken along the line Z2-Z2′. As illustrated in FIG. 5KD, the poly-Si layers 23a, 23b, and 23c extending in the X-X′ line direction are formed to surround the gate insulating layers 36a and 36b. As illustrated in FIG. 5KE, the poly-Si layers 25aa and 25ba that cover the gate insulating layer 36a and are isolated from each other and the poly-Si layers 25bb and 25ca that cover the gate insulating layer 36b and are isolated from each other are formed to extend in the X-X′ line direction. The poly-Si layer 23a is connected to the first plate line PL1, the poly-Si layer 23b is connected to the second plate line PL2, and the poly-Si layer 23c is connected to a third plate line PL3. As illustrated in FIG. 5KE, the poly-Si layer 25aa is connected to a first word line WL1, the poly-Si layer 25ba is connected to a second word line WL2, the poly-Si layer 25bb is connected to a third word line WL3, and the poly-Si layer 25ca is connected to a fourth word line WL4. By operating the poly-Si layers 25aa and 25ba synchronously, the same operation as that of the third gate conductor layer 5c illustrated in FIG. 1A can be performed. One of the poly-Si layers 25aa and 25ba may function as the third gate conductor layer 5c, and the other of the poly-Si layers 25aa and 25ba may function as an electrostatic shield layer against the voltage change of the adjacent word line. In this manner, four dynamic flash memory cells are formed on the P-layer substrate 20.

The gate insulating layers 36a and 36b may be formed as a single-layer or multilayer material layer that functions as a gate insulating layer. Likewise, as the poly-Si layers 23a, 23b, 23c, 25a, 25b, and 25c, a single-layer or multilayer conductor material layer that functions as a gate conductor layer may be used.

Instead of the P-layer substrate 20, an SOI substrate or a well substrate using a P-layer and an N-layer may be used.

In FIGS. 5AA to AC, the insulating material layers 27a, 27b, 27c, and 27d having a circular shape in plan view are formed. The insulating material layers 27a, 27b, 27c, and 27d may have an elliptical or rectangular shape in plan view. Each of the insulating material layers 27a, 27b, 27c, and 27d may be composed of another single-layer or multilayer material layer.

The SiO₂ layer 26 illustrated in FIGS. 5AA to 5AC may be formed by oxidizing the poly-Si layer 25, for example. Alternatively, the SiO₂ layer 26 may be omitted. When the insulating material layers 27a to 27d are formed, an insulating layer corresponding to the SiO₂ layer 26 may be formed at respective lowermost portions.

The present embodiment has features below.

(Feature 1) In the first embodiment of the present invention illustrated in FIGS. 1A and 1B, the first gate conductor layer 5a connected to the first plate line PL1 and the second gate conductor layer 5b connected to the second plate line PL2 are isolated from each other around the first gate insulating layer 4. The voltage applied to the second plate line PL2 is set to be lower than the voltage applied to the first plate line PL1, so that a group of holes is accumulated in a portion of the channel region 7a closer to the second gate conductor layer 5b connected to the second plate line PL2. This configuration enables accumulation of more holes than in a structure in which the entire channel region 7a is surrounded by a single gate electrode. In a read operation, the floating body voltage of the channel region 7a can be controlled by the voltage applied to the second gate conductor layer 5b. Thus, a more stable back bias effect can be maintained in the read operation. With these configurations, a dynamic flash memory cell having a wider operation margin can be implemented.

(Feature 2) As illustrated in FIGS. 5BA to 5BC, when the separate insulating material layers 27a and 27b are present, the SiN layer 30a surrounding the separate insulating material layers 27a and 27b can be formed to have the equal width L1 in plan view by using the CVD method and the RIE method. By using this configuration, the length L2 between the intersections where the outer periphery edges of the insulating material layers 27a and 27b intersect with the line X-X′ is set to be smaller than twice the width L1, so that the SiN layer 30a that is continuous and surrounds the side surfaces of the insulating material layers 27a and 27b is formed. The SiN layer 30b is formed in the similar manner. The length L3 between the intersections where the outer periphery edges of the insulating material layers 27a and 27c intersect with the line Y-Y′ is set to be larger than twice the width L1, so that the SiN layer 30a and the SiN layer 30b are formed to be separate from each other. The insulating material layers 27a and 27b and the SiN layers 30a and 30b are removed by etching, and the gate insulating layers 36a and 36b and the P-layer Si pillars 40a to 40d, each of which is the Si pillar 2 illustrated in FIGS. 1A and 1B, are formed in the holes 35a and 35b that are formed by using the mask material layers 31a and 31c as etching masks. Thus, an increased density of the dynamic flash memory can be implemented in the X-X′ line direction.

(Feature 3) According to the production method according to the present embodiment, as illustrated in FIGS. 5KD and 5KE, the gate insulating layer 36a is formed between the P-layer Si pillars 40a and 40b and the gate insulating layer 36b is formed between the P-layer Si pillars 40c and 40d. Thus, the poly-Si layers 23a, 23b, and 23c that are isolated from each other, extend in the X-X′ line direction, and are respectively connected to the first to third plate lines (PL1 to PL3) can be formed without using the lithography process and the RIE etching process. Therefore, the process is simplified.

### Second Embodiment

FIGS. 6AA to 6AC illustrate a method of producing a memory device including four dynamic flash memory cells according to a second embodiment formed on a substrate 20. FIG. 6AA is a plan view. FIG. 6AB is a vertical sectional view taken along line X-X′ in FIG. 6AA. FIG. 6AC is a vertical sectional view taken along line Y-Y′ in FIG. 6AC. FIGS. 6BD and 6BE are plan views of cross-sections taken along line Z1-Z1′ and line Z2-Z2′ in FIG. 6AB. FIG. 6BD is a plan view of the cross-section taken along the line Z1-Z1′. FIG. 6BE is a plan view of the cross-section taken along the line Z2-Z2′. In an actual memory device, more than four dynamic flash memory cells are arranged in a matrix shape.

The same steps as those illustrated in FIGS. 5AA to 5IC are performed. In the first embodiment, as illustrated in FIGS. 5HA to 5HC and 5IA to 5IC, etching of the poly-Si layers 25a to 25c is stopped above the SiO₂ layers 24a to 24c, and the poly-Si layers 25aa, 25ba, 25bb, and 25ca are formed. By contrast, in the present embodiment, as illustrated in FIGS. 6AA to 6AC, this etching is performed on the SiO₂ layers 24a to 24c and the poly-Si layers 23a to 23c to form SiO₂ layers 24aa, 24ba, 24bb, and 24ca that are isolated from one another and poly-Si layers 23aa, 23ba, 23bb, and 23ca that are isolated from one another. Then, the step illustrated in FIGS. 5JA to 5JC is performed to form a dynamic flash memory on the P-layer Si pillar substrate 20.

Consequently, as illustrated in FIG. 6BD, the poly-Si layers 23aa and 23ba that surround the gate insulating layer 36a, extend in the X-X′ line direction, and are isolated from each other in plan view are formed. Likewise, the poly-Si layers 23bb and 23ca that surround the gate insulating layer 36b, extend in the X-X′ line direction, and are isolated from each other are formed. The poly-Si layers 23ba and 23bb are connected to the second plate lines PL21 and PL22 that are isolated from each other. FIG. 6BE is the same as FIG. 5KE.

After the poly-Si layers 23aa, 23ba, 23bb, 23ca, 25aa, 25ba, 25bb, and 25ca are formed, the poly-Si layers 23aa, 23ba, 23bb, 23ca, 25aa, 25ba, 25bb, and 25ca may be removed by etching and new gate conductor layers may be formed again.

In FIGS. 1A and 1B, the first gate conductor layer 5a is connected to the first plate line PL1, the second gate conductor layer 5b is connected to the second plate line PL2, and the third gate conductor layer 5c is connected to the word line WL. By contrast, the first gate conductor layer 5a connected to the first plate line PL1 and the second gate conductor layer 5b connected to the second plate line PL2 may be formed in an upper portion, and the third gate conductor layer 5c connected to the word line WL may be formed in a lower portion in the vertical direction. A dynamic flash memory may be produced also in this manner. The same applies to FIGS. 5AA to 5KE.

In FIGS. 1A and 1B, the third gate conductor layer 5c connected to the word line WL may be divided into two portions, similarly to the first gate conductor layer 5a connected to the first plate line PL1 and the second gate conductor layer 5b connected to the second plate line PL2. A dynamic flash memory may be produced also in this manner. The same applies to FIGS. 5AA to 5KE.

The present embodiment has features below. As illustrated in FIG. 6BD, the poly-Si layers 23ba and 23bb are respectively connected to the second plate lines PL21 and PL22 that are isolated from each other. Thus, the floating body voltage of the P-layer Si pillars 40a and 40b and the floating body voltage of the P-layer Si pillars 40c and 40d can be controlled independently from each other by the voltage applied to the second plate line PL21 and the voltage applied to the second plate line PL22, respectively. Therefore, for example, an erase operation of discharging a group of holes accumulated in the P-layer Si pillars 40a and 40b can be performed by applying pulse voltages to the poly-Si layers 23aa and 23ba while stably holding the group of holes in the P-layer Si pillars 40c and 40d.

### Third Embodiment

FIGS. 7A and 7B illustrate a method of producing a memory device including four dynamic flash memory cells according to a third embodiment formed on a P-layer Si pillar substrate 20. FIG. 7A is a plan view corresponding to FIG. 5KD, and FIG. 7B is a plan view corresponding to FIG. 5KE.

In the first embodiment, as illustrated in FIG. 5KE, the poly-Si layers 25aa, 25ba, 25bb, and 25ca that are isolated from one another are formed. By contrast, in the present embodiment, as illustrated in FIG. 7B, a poly-Si layer 25B is formed without division into the poly-Si layers 25ba and 25bb. FIG. 7A is the same as FIG. 5KD. Other steps are the same as those illustrated in FIGS. 5AA to 5JC.

The present embodiment has features below. For example, a ground voltage is applied to the poly-Si layer 25B connected to a word line WL5. This allows the poly-Si layer 25B to function as an electrostatic shield layer between the poly-Si layers 25aa and 25ca. Thus, a stable operation of the dynamic flash memory can be performed.

### Fourth Embodiment

FIGS. 8AA to 8AC and 8BA to 8BC illustrate a method of producing a memory device including four dynamic flash memory cells according to a fourth embodiment formed on a substrate 20. FIGS. 8AA and 8BA are plan views. FIGS. 8AB and 8BB are vertical sectional views taken along line X-X′ in FIGS. 8AA and 8BA, respectively. FIGS. 8AC and 8BC are vertical sectional views taken along line Y-Y′ in FIGS. 8AA and 8BA, respectively. In an actual memory device, more than four dynamic flash memory cells are arranged in a matrix shape.

The steps illustrated in FIGS. 5AA to 5HC are performed. Then, the mask material layers 31a, 31b, and 31c are removed. Then, an insulating layer (not illustrated) is deposited to cover the entire surface. Then, as illustrated in FIGS. 8AA to 8AC, the entire surface is etched by the RIE method to form insulating layers 50aa, 50ba, 50bb, and 50ca on the side surfaces of the gate insulating layers 36a and 36b.

Next, as illustrated in FIGS. 8BA to 8BC, the SiO₂ layers 26a, 26b, and 26c and the poly-Si layers 25a, 25b, and 25c are etched by using the insulating layers 50aa, 50ba, 50bb, and 50ca as masks to form SiO₂ layers 26Aa, 26Ba, 2Bb, and 26Ca and poly-Si layers 25Aa, 25Ba, 25Bb, and 25Ca. Then, the step illustrated in FIGS. 5JA to 5JC is performed. In this manner, four dynamic flash memory cells are formed on the P-layer substrate 20.

As the insulating layers 50aa, 50ba, 50bb, and 50ca, another organic or inorganic material layer that serves as etching masks for the SiO₂ layers 26a, 26b, and 26c and the poly-Si layers 25a, 25b, and 25c may be used.

As illustrated in FIGS. 6AA to 6AC, the SiO₂ layers 24a, 24b, and 24c and the poly-Si layers 23a, 23b, and 23c may be etched by using the insulating layers 50aa, 50ba, 50bb, and 50ca as masks.

The present embodiment has features below. The insulating layers 50aa, 50ba, 50bb, and 50ca serving as etching masks are formed by self-alignment with the P-layer Si pillars 40a to 40d without using a photolithography process. Thus, the process can be simplified and the accuracy can be increased.

### Other Embodiments

In the first embodiment illustrated in FIGS. 5AA to 5KE, the P-layer Si pillars 40a to 40d are formed. However, the pillars may be formed using Si or a semiconductor material other than Si. This also applies to the other embodiments of the present invention.

The N⁺ layers 3a and 3b in the first embodiment illustrated in FIG. 1A may be formed by a Si layer or another semiconductor material layer containing a donor impurity. Alternatively, the N⁺ layers 3a and 3b may be formed by different semiconductor material layers. The N⁺ layers may be formed by using the epitaxial crystal growth method or another method. This also applies to the other embodiments of the present invention.

The poly-Si layers 23a to 23c and 25aa to 25ca illustrated in FIGS. 5JA to 5JC each may be replaced with a combination of a single material layer or a plurality of material layers. This also applies to the other embodiments of the present invention.

In FIGS. 5HA to 5HC, one or both of the poly-Si layers 23a, 23b, and 23c and the poly-Si layers 25a, 25b, and 25c may be removed, and gate conductor layers may be filled again. Alternatively, in FIGS. 5IA to 5IC, after the poly-Si layers 23a, 23b, and 23c and the poly-Si layers 25aa, 25ba, 25bb, and 25ca are formed, gate conductor layers may be filled again. This also applies to the other embodiments of the present invention.

The protective layer 37 illustrated in FIGS. 5FA to 5FC may be any layer that functions as a protective film for protecting the gate insulating layer 36 in etching based on the RIE method. Likewise, the SiN layers 30a and 30b each may be another material layer that functions as an etching mask. This also applies to the other embodiments of the present invention.

In FIGS. 1A and 1B, the Si pillar 2 has a circular shape in plan view. Alternatively, the Si pillar 2 may have an elliptical shape, a shape elongated in one direction, or the like in plan view. The dynamic flash memory cell can be constituted by Si pillars having different shapes in plan view. These apply to the other embodiments according to the present invention.

In the description of FIGS. 5AA to 5KE, the P-layer Si pillars 40a to 40d have a rectangular vertical section. Alternatively, the P-layer Si pillars 40a to 40d may have a trapezoidal vertical section. This also applies to the other embodiments of the present invention.

A conductor layer, for example, a W layer, may be connected to the N⁺ layer 21 that is connected to the bottom portions of the P-layer Si pillars 40a to 40d in FIGS. 5AA to 5KE. This also applies to the other embodiments of the present invention.

FIGS. 5AA to 5KE present an example in which the P-layer Si pillars 40a to 40d are arranged in a square lattice manner in plan view. Alternatively, the P-layer Si pillars 40a to 40d may be arranged in an orthorhombic lattice manner or a zigzag manner. This also applies to the other embodiments of the present invention.

To decrease the electric resistance, a buried conductor layer may be disposed in the N⁺ layer 21 in FIGS. 5AA to 5AC. The buried conductor layer may be disposed in the N⁺ layer 21 in a subsequent step, for example, after the formation of the P-layer Si pillars 40a to 40d. This buried conductor layer is connected to the source line SL. The N⁺ layer 21 may be formed to be continuous between the P-layer Si pillars 40a and 40c and continuous between the P-layer Si pillars 40b and 40d in plan view. In this case, the N⁺ layer of the P-layer Si pillars 40a and 40c and the N⁺ layer of the P-layer Si pillars 40b and 40d are electrically isolated from each other by, for example, shallow trench isolation (STD) or a well structure. In this case, a low-resistance conductor layer such as a W layer is desirably disposed adjacently to the isolated N⁺ layers. This also applies to the other embodiments of the present invention.

In FIGS. 5AA to 5KE, a light doped drain (LDD) region including a N-layer having a lower impurity concentration than the N⁺ layers 21 and 41a to 41d, or a P-layer that has an overlap with or is separate from ends of the poly-Si layers 23a to 23c and 25aa to 25ca in the vertical direction may be provided between the N⁺ layer 21 and the P-layer Si pillars 40a to 40d and between the P-layer Si pillars 40a to 40d and the N⁺ layers 41a to 41d. This also applies to the other embodiments of the present invention.

Various embodiments and modifications can be made to the present invention without departing from the broad spirit and scope of the present invention. The embodiments described above are for describing an example of the present invention, and do not limit the scope of the present invention. The embodiments and modifications described above can be combined as desired. Even if some of the components of the above-described embodiment are omitted as necessary, such a configuration is also within the scope of the technical idea of the present invention.

With the method of producing a semiconductor device including a memory element according to the embodiments of the present invention, a semiconductor device including a high-density high-performance dynamic flash memory is obtained.

What is claimed is:

1. A method of producing a semiconductor device including a memory element configured to perform a data write operation, a data read operation, and a data erase operation by controlling voltages applied to a first gate conductor layer, a second gate conductor layer, a third gate conductor layer, a first impurity layer, a second impurity layer, and a third impurity layer, the method comprising:
forming a first semiconductor layer, a first insulating layer, a first gate material layer, a second insulating layer, and a second gate material layer on a substrate in a direction perpendicular to the substrate;
forming a first material layer and a second material layer above the second gate material layer, the first material layer and the second material layer being separate from each other and adjacent to each other in a first direction in plan view;
forming a third material layer that is continuous and surrounds side surfaces of the first material layer and the second material layer;
forming a fourth material layer that is continuous and covers a side surface of the third material layer;
etching the first material layer, the second material layer, the third material layer, the second gate material layer, the second insulating layer, the first gate material layer, and the first insulating layer using the fourth material layer as a mask to form a first hole extending in the first direction in plan view;
forming a first gate insulating layer in the first hole to form a second hole and a third hole that are separate from each other by the first gate insulating layer;
removing the first gate insulating layer at bottom portions of the second hole and the third hole;
forming a first semiconductor pillar and a second semiconductor pillar respectively in the second hole and the third hole by deposition or crystal growth of semiconductor atoms;
forming the first gate conductor layer and the second gate conductor layer that are divisional portions of the first gate material layer divided by the first gate insulating layer and forming the third gate conductor layer that is the second gate material layer, or forming the first gate conductor layer, the second gate conductor layer, and the third gate conductor layer by removing the first gate material layer and the second gate material layer and filling spaces caused by the removal; and
forming the second impurity layer on the first semiconductor pillar and forming the third impurity layer on the second semiconductor pillar, wherein
the first semiconductor layer is the first impurity layer.

2. The method according to claim 1, wherein
a distance between an outer periphery edge of the first material layer and an outer periphery edge of the second material layer on a center line of the first material layer and the second material layer arranged in the first direction is set to be smaller than twice a thickness of the third material layer on a line passing through a center of the first material layer in a second direction orthogonal to the first direction, and
the first gate insulating layer is formed such that the second hole and the third hole separated from each other are formed.

3. The method according to claim 1, wherein the first gate insulating layer is formed such that a length between an outer periphery edge of the second hole and an outer periphery edge of the third hole that intersect with a center line passing through a center of the second hole and a center of the third hole in the first direction is smaller than twice a thickness of the first gate insulating layer on a line that passes through a center of the first material layer and is orthogonal to the first direction in plan view.

4. The method according to claim 1, wherein the third gate conductor layer is divided by the first hole to form a fifth gate conductor layer and a sixth gate conductor layer.

5. The method according to claim 1, wherein
a wiring connected to the first impurity layer is a source line, a wiring connected to the second impurity layer is a bit line, one of a wiring connected to the first or second gate conductor layer and a wiring connected to the third gate conductor layer is connected to a plate line, and the other of the wiring connected to the first or second gate conductor layer and the wiring connected to the third gate conductor layer is connected to a word line, and
the data erase operation, the data read operation, and the data write operation are performed based on voltages applied to the source line, the bit line, the plate line, and the word line.

6. The method according to claim 1, further comprising:
forming a fourth hole that is parallel to the first hole extending in the first direction in plan view, the fourth hole being formed when the first hole is formed;
forming, in the fourth hole, a second gate insulating layer, a third semiconductor pillar, and a fourth semiconductor pillar when the first gate insulating layer, the first semiconductor pillar, and the second semiconductor pillar are formed, the third semiconductor pillar and the fourth semiconductor pillar being isolated from each other by the second gate insulating layer; and
forming a fourth impurity layer on the third semiconductor pillar and a fifth impurity layer on the fourth semiconductor pillar, wherein
the first hole and the fourth hole are formed to be separate from each other in the second direction in plan view.

7. The method according to claim 6, wherein one or both of the first gate conductor layer and the second gate conductor layer located between a row of the first and second semiconductor pillars and a row of the third and fourth semiconductor pillars are formed to have two divisional portions and extend in the first direction in plan view.

8. The method according to claim 6, wherein either the first gate conductor layer or the second gate conductor layer located between a row of the first and second semiconductor pillars and a row of the third and fourth semiconductor pillars is continuous between the row of the first and second semiconductor pillars and the row of the third and fourth semiconductor pillars and extends in the first direction in plan view.

9. The method according to claim 6, wherein the third gate conductor layer located between a row of the first and second semiconductor pillars and a row of the third and fourth semiconductor pillars is formed to have two divisional portions and extend in the first direction in plan view.

10. The method according to claim 1, further comprising:
removing the fourth material layer after forming the first semiconductor pillar and the second semiconductor pillar;
forming a mask material layer surrounding an outer periphery portion of a top portion of the first semiconductor pillar and an outer peripheral portion of a top portion of the second semiconductor pillar; and
etching the second gate material layer by using the mask material layer as a mask to form the third gate conductor layer.

11. The method according to claim 10, further comprising:
etching the second gate material layer, the first insulating layer, and the first gate material layer by using the mask material layer as a mask to form the first gate conductor layer, the second gate conductor layer, and the third gate conductor layer that has two divisional portions.

12. The method according to claim 1, further comprising:
after the forming of the first gate insulating layer in the first hole to form the second hole and the third hole that are separate from each other by the first gate insulating layer, forming a first protective film on an entire surface;
removing the first protective film and the first gate insulating layer at the bottom portions of the second hole and the third hole by etching; and
removing the remaining first protective film.

13. The method according to claim 1, further comprising:
forming the first gate conductor layer, the second gate conductor layer, the third gate conductor layer, the first impurity layer, the second impurity layer, and the third impurity layer that enable the data write operation of holding, in one or both of the first semiconductor pillar and the second semiconductor pillar, a group of holes or a group of electrons that is a majority carrier of the first semiconductor pillar and the second semiconductor pillar and is generated by an impact ionization phenomenon or a gate-induced drain leakage current, by controlling voltages applied to the first gate conductor layer, the second gate conductor layer, the third gate conductor layer, the first impurity layer, the second impurity layer, and the third impurity layer and that enable the group of holes or the group of electrons that is the majority carrier of the first semiconductor pillar and the second semiconductor pillar to be discharged from one or both of the first semiconductor pillar and the second semiconductor pillar by controlling voltages applied to the first gate conductor layer, the second gate conductor layer, the first impurity layer, the second impurity layer, and the third impurity layer.
